(19) United States
(12) Patent Application Publication
(10) Pub. No.: US 2026/0282316 A1
(43) Pub. Date: Sep. 17, 2026

(54) MEMORY AND PREPARATION METHOD THEREFOR, AND ELECTRONIC DEVICE

(71) Applicant: BEIJING SUPERSTRING ACADEMY OF MEMORY TECHNOLOGY, Beijing (CN)

(72) Inventors: Zhengyong ZHU, Beijing (CN); Bok Moon KANG, Beijing (CN); Chao ZHAO, Beijing (CN)

(21) Appl. No.: 19/479,709

(22) PCT Filed: Oct. 26, 2023
(86) PCT No.: PCT/CN2023/126749

§ 371 Date: Oct. 28, 2025

(30) Foreign Application Priority Data
May 12, 2023 (CN) 202310534005.1

(51) Int. Cl. H10B 12/00

(52) U.S. Cl. CPC H10B 12/00

(57) ABSTRACT

The present disclosure relates to the technical field of integrated circuit design and manufacturing, and in particular relates to a memory and a preparation method therefor, and an electronic device, which are used for reducing the processing complexity and costs of a prepared product while improving the data bandwidth each time the prepared product is accessed. The memory comprises a plurality of memory cells 100 stacked in the thickness direction perpendicular to the surface of a substrate (10); a write word line (20) and a read word line (30), both extending in a second direction parallel to the surface of the substrate (10); a write bit line (60) and a read bit line (90), both extending to the substrate (10) in a direction perpendicular to the substrate (10); a write transistor (70), comprising a source contact region, a channel region, and a drain contact region sequentially distributed in the second direction; a read transistor (101), comprising a back gate and a source contact region, a channel region, and a drain contact region sequentially distributed in the second direction, the back gate being located between the write word line (20) and the read transistor (101).

### CROSS-REFERENCE TO RELATED APPLICATION

This application is national stage of International Application No. PCT/CN 2023/126749 filed on Oct. 26, 2023, which claims the priority of Chinese Patent Application No. 202310534005.1, filed to the China National Intellectual Property Administration on May 12, 2023, and entitled “MEMORY AND PREPARATION METHOD THEREFOR, AND ELECTRONIC DEVICE”, the disclosure of which is incorporated herein by reference in its entirety.

### TECHNICAL FIELD

The disclosure relates to the technical field of integrated circuit design and manufacturing, and in particular to a memory, a preparation method for a memory and an electronic device.

### BACKGROUND

With the continuous development of integrated circuit manufacturing processes, the market has increasingly higher requirements for the capacity, preparation cost and data transmission rate of storage products, making three-dimensional stacked storage structures an important development direction.

For example, in the field of dynamic random access memory (DRAM), two-dimensional memory arrays pose significant challenges to process and manufacturing equipment in terms of miniaturization. Stacking multiple layers of two-dimensional memory cell arrays in the vertical direction has become a technological development trend to achieve high-density storage.

### SUMMARY

According to various embodiments of the disclosure, a memory, a preparation method for the memory and an electronic device are provided.

In some embodiments, an aspect of the disclosure provides a memory. The memory includes: a substrate, write word lines, read word lines, write bit lines, read bit lines, and multiple memory cells stacked in a direction perpendicular to the substrate. Each of the memory cells includes a write transistor and a read transistor, which are located between a respective write word line and a respective read word line and are sequentially distributed in a first direction parallel to the substrate. Each of the write bit lines and each of the read bit lines are located between a respective write word line and a respective read word line and are connected to a respective write transistor and a respective read transistor, respectively. Each of the write word lines and each of the read word lines extend in a second direction parallel to the substrate, and the write bit line and the read bit line extend in the direction perpendicular to the substrate. Each read transistor includes a back-gate and a first semiconductor layer. The first semiconductor layer extends in the second direction and surrounds the respective read word line. The first semiconductor layer includes: a source contact region, a drain contact region and a channel region located between the source contact region and the drain contact region, which are sequentially distributed along the second direction. The back-gate is located between the respective write word line and the channel region of the read transistor. Each write transistor includes a second semiconductor layer extending along the second direction and surrounding the respective write word line. The second semiconductor layer includes: a source contact region, a drain contact region and a channel region located between the source contact region and the drain contact region, which are sequentially distributed along the second direction. The first direction intersects the second direction.

In some embodiments, the back-gate includes at least a gate conductive layer and a gate dielectric layer. The memory further comprises: at least one first via that is located between the write word lines and the read word lines and penetrates through the memory cells, and the gate dielectric layer and the gate conductive layer are sequentially disposed on sidewalls of each first via. The gate conductive layers corresponding to memory cells in different layers are insulated from each other through a respective dielectric layers. A region of the gate conductive layer in the first via that is close to a respective write transistor is connected to the source contact region of this write transistor, and a region of the gate conductive layer in the first via that is close to a respective read transistor is connected to this read transistor through the gate dielectric layer.

In some embodiments, an opening is disposed in a region of the gate dielectric layer that is close to the respective write transistor, and the gate conductive layer is connected to this write transistor at the opening in the region.

In some embodiments, the gate conductive layer in the at least one first via surrounds the sidewalls of the first via.

In some embodiments, in a region of the first via that corresponds to the gate conductive layer, an aperture of the region that is close to a middle region of the gate conductive layer is larger than an aperture of the region that is close to each of two end regions of the gate conductive layer, and the gate dielectric layer forms an adaptive structure based on a shape of the first via.

In some embodiments, the first semiconductor layer has two opposite main surfaces that are a first side and a second side of the first semiconductor layer, respectively. The first side faces away from the respective read word line, and the second side faces toward this read word line. The first semiconductor layer includes the source contact region of the read transistor, the drain contact region of the read transistor, and the channel region located between the source contact region and the drain contact region, which are spaced apart from each other on the first side.

In some embodiments, the first semiconductor layer surrounds sidewalls of the respective read word line and is insulated from this read word line. The first side of the first semiconductor layer includes an upper surface, a lower surface and a side surface. The source contact region, the channel region and the drain contact region of the read transistor are at least partially located on the side surface and sequentially disposed in an extending direction of the read word line.

In some embodiments, the memory further includes a second via and multiple conductive layers located on a sidewall of the second via. The second via is close to the channel regions of the write transistors and penetrates through each of memory cells in each layer. The conductive layers corresponding to memory cells in different layers are insulated from each other. The second via exposes the source contact regions of the write transistors and the gate conductive layers of the memory cells in each layer. Each conductive layer is located on the sidewall of the second via and forms a ring structure. The ring structure is simultaneously connected to the gate conductive layer exposed by the second via and the source contact region of the write transistor.

In some embodiments, the channel region of the read transistor, the first via, the second via and the source contact region of the write transistor covers at least one straight line parallel to the first direction.

In some embodiments, the second semiconductor layer has two opposite main surfaces that are a first side and a second side of the second semiconductor layer, respectively. The first side faces away from the respective write word line, and the second side faces toward this write word line. The second semiconductor layer includes the source contact region of the write transistor, the drain contact region of the write transistor, and the channel region located between the source contact region and the drain contact region, which are spaced apart from each other on the first side.

In some embodiments, the second semiconductor layer surrounds sidewalls of the respective write word line and is insulated from the write word line. The first side of the second semiconductor layer includes an upper surface, a lower surface and a side surface. The source contact region, the channel region and the drain contact region of the write transistor are at least partially located on the side surface and sequentially disposed in an extending direction of the write word line.

In some embodiments, the memory further includes a reference line in the direction perpendicular to the substrate. The reference line extends along the direction perpendicular to the substrate and penetrates through the memory cells and connects to the read transistors of the memory cells. The read bit line, the back-gate and the reference line are sequentially arranged in the second direction.

In some embodiments, the write bit line and the respective read bit line are on a same side facing away from the respective back-gate in the second direction.

In some embodiments, another aspect of the disclosure provides an electronic device. The electronic device includes the memory as described in any one of the embodiments of the disclosure.

In some embodiments, yet another aspect of the disclosure provides a preparation method for a memory. The preparation method includes the following operations. A substrate is provided. A stacked structure is formed on the substrate. The stacked structure includes sacrificial layers and dielectric layers that are alternately stacked in sequence in a direction perpendicular to the substrate. Write word lines, read word lines, write bit lines, read bit lines, and multiple memory cells stacked in the direction perpendicular to the substrate are formed on the substrate based on the stacked structure. Each memory cell includes a write transistor and a read transistor, which are located between the respective write word line and the respective read word line and sequentially distributed along a first direction parallel to the substrate. For each of the write word lines and each of the read word lines, the write word line and the read word line extend along a second direction parallel to the substrate. For each of the write bit lines and each of the read bit lines, the write bit line and the read bit line extend along the direction perpendicular to the substrate, are located between the respective write word line and the respective read word line, and are connected to the respective write transistor and the respective read transistor, respectively. Each read transistor includes a back-gate and a first semiconductor layer. The first semiconductor layer extends along the second direction and surrounds the respective read word line. The first semiconductor layer includes a source contact region, a drain contact region and a channel region located between the source contact region and the drain contact region, which are sequentially distributed along the second direction. The back-gate is located between the respective write word line and the channel region of the read transistor. Each write transistor includes a second semiconductor layer that extends along the second direction and surrounds the respective write word line. The second semiconductor layer includes a source contact region, a drain contact region and a channel region located between the source contact region and the drain contact region, which are sequentially distributed along the second direction. The first direction intersects the second direction.

In some embodiments, the operation that the write word lines, the read word lines, the write bit lines, the read bit lines, and the multiple memory cells stacked in the direction perpendicular to the substrate are formed on the substrate based on the stacked structure includes the following operations. Two isolation trenches are formed on the stacked structure, extend in the second direction and penetrate through the stacked structure. Two isolation trenches respectively expose sacrificial layers and dielectric layers, and the sacrificial layers and the dielectric layers are located on two opposite sidewalls of the stacked structure, respectively. Each of the exposed sacrificial layers is etched back to form a first accommodating groove and a second accommodating groove, which are located on two opposite sidewalls of the exposed sacrificial layer, respectively. An initial semiconductor layer, a gate dielectric layer and a word line material layer are sequentially formed on inner walls of the first accommodating grooves and are sequentially formed inner walls of the second accommodating grooves. The word line material layer located in the first accommodating grooves is used to form the respective write word lines, and the word line material layer located in the second accommodating grooves is used to form the respective read word lines. A portion of the initial semiconductor layer, a portion of the gate dielectric layer and a portion of the word line material layer that are located within the isolation trench are removed, to disconnect semiconductor layers and word lines of two memory cells adjacent in the first direction to form: initial first semiconductor layers that are disconnected from each other across different layers, initial second semiconductor layers that are disconnected from each other across different layers, read word lines that are disconnected from each other across different layers, and write word lines that are disconnected from each other across different layers.

In some embodiments, after the operation that the write word lines and the read word lines are formed, the preparation method further includes the following operations. First trenches and second trenches, which extend in the first direction and are spaced apart from each other in the second direction, are formed in the stack structure, to define a shape and a position of a single memory cell. Each first trench and each second trench disconnect the respective initial first semiconductor layer and the respective initial second semiconductor layer, and expose a portion of the substrate, a portion of an outer surface of the gate dielectric layer on the word line material layer that is close to the sacrificial layer, to disconnect the second semiconductor layers between different memory cells connected through a same write word line and the first semiconductor layers between different memory cells connected through a same read word line. The first trench and the second trench are filled with an insulating layer to form a first insulating structure and a second insulating structure.

In some embodiments, the first insulating structure has a bent portion extending along the second direction. The second semiconductor layer has two opposite main surfaces that are a first side and a second side of the second semiconductor layer, respectively. The first side faces away from the respective write word line, and the second side faces toward this write word line. The second semiconductor layer includes the source contact region of the write transistor, the drain contact region of the write transistor and the channel region located between the source contact region and the drain contact region, which are spaced apart from each other on the first side. After the operation that the first insulating structure and the second insulating structure are formed, the preparation method further includes the following operations. The stacked structure is etched in the direction perpendicular to the substrate, to obtain a first sub-via that exposes a portion of the substrate and is located in a region surrounded by the first insulating structure and the write word line. The sacrificial layer is etched in the first direction and the second direction through the first sub-via, to obtain a first accommodating recess for defining a channel length of the write transistor. A portion of a side surface of the second semiconductor layer that is exposed by the first accommodating recess is used to form the channel region of the write transistor. An isolation layer is formed in the first accommodating recess, to form write transistors that are insulated from each other in the direction perpendicular to the substrate.

In some embodiments, the first semiconductor layer has two opposite main surfaces that are a first side and a second side of the first semiconductor layer, respectively. The first side faces away from the respective read word line, and the second side faces toward this read word line. The first semiconductor layer includes the source contact region of the read transistor, the drain contact region of the read transistor, and the channel region located between the source contact region and the drain contact region, which are spaced apart from each other on the first side. After the operation that the isolation layer is formed in the first accommodating recess, the preparation method further includes the following operations. The stacked structure is etched in the direction perpendicular to the substrate, to obtain a second sub-via that exposes a portion of the substrate and is located between the bent portion of the first insulating structure and the first semiconductor layer. The sacrificial layer is etched in the first direction and the second direction through the second sub-via, to obtain a second accommodating recess for defining a channel length of the read transistor. A portion of a side surface of the first semiconductor layer that is exposed by the second accommodating recess is used to form the channel region of the read transistor. A gate dielectric layer and a gate conductive layer are sequentially formed in the second accommodating recess, to obtain the second sub-via. The gate dielectric layer covers an inner wall of the second sub-via. An insulating layer is formed in the second sub-via, to form back-gates that are insulated from each other in the direction perpendicular to the substrate. The insulating layer, the gate conductive layer and the gate dielectric layer are used to jointly form the back-gate.

In some embodiments, after the operation that the insulating layer is formed in the second sub-via, the preparation method further includes the following operations. The stacked structure is etched in the direction perpendicular to the substrate, to obtain a third sub-via that exposes a portion of the substrate and is located in a region surrounded by the second insulating structure, the back-gate, the first insulating structure and the second semiconductor layer. The sacrificial layer is etched in the first direction and the second direction through the third sub-via, to obtain a third accommodating recess that exposes the source contact region of the write transistor and the gate conductive layer of the back-gate. A conductive layer is formed in the third accommodating recess to obtain the third sub-via. An insulating layer is formed in the third sub-via. A fourth sub-via is formed in a region surrounded by the bent portion of the second insulating structure and the first semiconductor layer. The fourth sub-via exposes the source contact region of the read transistor. A reference line is formed in the fourth sub-via. A fifth sub-via is formed in a region surrounded by the bent portion of the first insulating structure and the first semiconductor layer. The fifth sub-via exposes the drain contact region of the read transistor. The respective read bit line is formed in the fifth sub-via. A sixth sub-via is formed in a region surrounded by the bent portion of the first insulating structure and the second semiconductor layer. The sixth sub-via exposes the drain contact region of the write transistor. The respective write bit line is formed in the sixth sub-via.

The details of one or more embodiments of the disclosure will be set forth in the following drawings and description. Other features, objectives, and advantages of the disclosure will be apparent from the description, the drawings, and the claims.

### BRIEF DESCRIPTION OF THE DRAWINGS

In order to illustrate the technical solutions in the embodiments of the disclosure more clearly, drawings to be used in the description of the embodiments will be briefly introduced below. It is apparent that the drawings in the following description are only some embodiments of the disclosure. For those skilled in the art, other drawings can also be obtained according to these drawings without the exercise of inventive effort.

FIG. 1 is a schematic flowchart of a preparation method for a semiconductor device according to some embodiments of the disclosure.

FIG. 2A is a top-view schematic diagram of a stacked structure provided in operation S20 according to some embodiments of the disclosure.

FIG. 2B is a schematic diagram of a cross-sectional structure obtained by taking a section of a three-dimensional structure illustrated in FIG. 2A in the AA′ direction.

FIG. 3A is a top-view schematic diagram of another stacked structure provided in the operation S20 according to some embodiments of the disclosure.

FIG. 3B is a schematic diagram of a cross-sectional structure obtained by taking a section of a three-dimensional structure illustrated in FIG. 3A in the AA′ direction.

FIG. 4A is a top-view schematic diagram of a structure obtained after forming a word line material layer in operation S614 according to some embodiments of the disclosure.

FIG. 4B is a schematic diagram of a cross-sectional structure obtained by taking a section of a three-dimensional structure illustrated in FIG. 4A in the AA′ direction.

FIG. 5A is a schematic diagram of a cross-sectional structure obtained by taking, in the AA′ direction, a section of the three-dimensional structure obtained after forming isolation trenches in a three-dimensional structure illustrated in FIG. 4A.

FIG. 5B is a schematic diagram of a cross-sectional structure obtained by taking, in the AA′ direction, a section of the three-dimensional structure obtained after forming isolation structures in a three-dimensional structure illustrated in FIG. 5A.

FIG. 6A is a top-view schematic diagram of a three-dimensional structure obtained after forming first insulating structures and second insulating structures in a three-dimensional structure illustrated in FIG. 5B.

FIG. 6B is a schematic diagram of a cross-sectional structure obtained by taking a section of a three-dimensional structure illustrated in FIG. 6A in the AA′ direction.

FIG. 6C is a schematic diagram of a cross-sectional structure obtained by taking a section of a three-dimensional structure illustrated in FIG. 6A in the EE′ direction.

FIG. 7A is a top-view schematic diagram of a structure obtained after forming first accommodating recesses in a three-dimensional structure illustrated in FIG. 6A.

FIG. 7B is a schematic diagram of a cross-sectional structure obtained by taking a section of a three-dimensional structure illustrated in FIG. 7A in the BB′ direction.

FIG. 8 is a schematic diagram of a cross-sectional structure obtained by taking, in the BB′ direction, a section of the three-dimensional structure obtained after forming isolation layers in a three-dimensional structure illustrated in FIG. 7A.

FIG. 9A is a top-view schematic diagram of a structure obtained after forming second accommodating recesses in a structure illustrated in FIG. 8.

FIG. 9B is a schematic diagram of a cross-sectional structure obtained by taking a section of a three-dimensional structure illustrated in FIG. 9A in the CC′ direction.

FIG. 10 is a schematic diagram of a cross-sectional structure obtained by taking, in the CC′ direction, a section of the three-dimensional structure obtained after forming gate conductive layers in a three-dimensional structure illustrated in FIG. 9B.

FIG. 11A is a top-view schematic diagram of a structure obtained after forming back-gates in a structure illustrated in FIG. 10.

FIG. 11B is a schematic diagram of a cross-sectional structure obtained by taking a section of a three-dimensional structure illustrated in FIG. 11A in the CC′ direction.

FIG. 12A is a top-view schematic diagram of a structure obtained after forming third accommodating recesses in a structure illustrated in FIG. 11A.

FIG. 12B is a schematic diagram of a cross-sectional structure obtained by taking a section of a three-dimensional structure illustrated in FIG. 12A in the CC′ direction.

FIG. 13A is a top-view schematic diagram of a structure obtained after forming interlayer conductive layers in a structure illustrated in FIG. 12A.

FIG. 13B is a schematic diagram of a cross-sectional structure obtained by taking a section of a three-dimensional structure illustrated in FIG. 13A in the CC′ direction.

FIG. 14A is a top-view schematic diagram of a structure obtained after forming interlayer dielectric layers in a structure illustrated in FIG. 13A.

FIG. 14B is a schematic diagram of a cross-sectional structure obtained by taking a section of a three-dimensional structure illustrated in FIG. 14A in the CC′ direction.

FIG. 15A is a top-view schematic diagram of a structure obtained after forming fifth sub-vias in a structure illustrated in FIG. 14A.

FIG. 15B is a schematic diagram of a cross-sectional structure obtained by taking a section of a three-dimensional structure illustrated in FIG. 15A in the BB′ direction.

FIG. 16 is a schematic diagram of a cross-sectional structure obtained by taking, in the BB′ direction, a section of the three-dimensional structure obtained after forming read bit lines in a three-dimensional structure illustrated in FIG. 15A.

FIG. 17A is a top-view schematic diagram of a structure obtained after forming fourth sub-vias in a structure illustrated in FIG. 16.

FIG. 17B is a schematic diagram of a cross-sectional structure obtained by taking a section of a three-dimensional structure illustrated in FIG. 17A in the DD′ direction.

FIG. 18 is a schematic diagram of a cross-sectional structure obtained by taking, in the DD′ direction, a section of the three-dimensional structure obtained after forming a reference line in a three-dimensional structure illustrated in FIG. 17A.

FIG. 19A is a top-view schematic diagram of a structure obtained after forming sixth sub-vias in a structure illustrated in FIG. 18.

FIG. 19B is a schematic diagram of a cross-sectional structure obtained by taking a section of a three-dimensional structure illustrated in FIG. 19A in the AA′ direction.

FIG. 20 is a top-view schematic diagram of a structure obtained after forming write bit lines in a structure illustrated in FIG. 19A.

FIG. 21A is a schematic diagram of a cross-sectional structure obtained by taking a section of a three-dimensional structure illustrated in FIG. 20 in the AA′ direction.

FIG. 21B is a schematic diagram of a cross-sectional structure obtained by taking a section of the three-dimensional structure illustrated in FIG. 20 in the BB′ direction.

FIG. 21C is a schematic diagram of a cross-sectional structure obtained by taking a section of the three-dimensional structure illustrated in FIG. 20 in the CC′ direction.

FIG. 21D is a schematic diagram of a cross-sectional structure obtained by taking a section of the three-dimensional structure illustrated in FIG. 20 in the DD′ direction.

FIG. 21E is a schematic diagram of a cross-sectional structure obtained by taking a section of the three-dimensional structure illustrated in FIG. 20 in the EE′ direction.

FIG. 22 is a circuit schematic diagram of a memory cell circuit according to some embodiments of the disclosure.

FIG. 23 is a circuit schematic diagram of a memory array circuit according to some embodiments of the disclosure.

### DETAILED DESCRIPTION

In order to facilitate understanding of the disclosure, reference will be made to relevant drawings to provide a more comprehensive description of the disclosure. The drawings illustrate preferred embodiment of the disclosure. However, the disclosure may be implemented in many different forms and is not limited to the embodiments described herein. Instead, these embodiments are provided to make the content of the disclosure more thorough and comprehensive.

Unless otherwise defined, all technical and scientific terms used herein have the same meanings as commonly understood by one skilled in the art to which the disclosure belongs. Herein, the terms used in the specification of the disclosure are only for the purpose of describing specific embodiments, and are not intended to limit the disclosure.

It should be understood that when an element or layer is referred to as being “on,” “adjacent to,” “connected to”, or “coupled to” another element or layer, it may be directly on, adjacent to, connected to, or coupled to the other element or layer, or there may be intervening element(s) or layer(s). In contrast, when an element or a layer is referred to as being “directly on,” “directly adjacent to,” “directly connected to,” or “directly coupled to” another element or layer, there are no intervening elements or layers present. It should be understood that although the terms “first”, “second”, “third”, etc. may be used to describe various elements, components, regions, layers, doping types and/or portions, these elements, components, regions, layers, doping types and/or portions should not be limited by these terms. These terms are merely used to distinguish one element, component, region, layer, doping type or portion from another element, component, region, layer, doping type or portion. Therefore, a first element, component, region, layer, doping type or portion discussed below may be referred to as a second element, component, region, layer, doping type or portion without departing from the teaching of the disclosure. For example, a first doping type may be referred to as a second doping type, and similarly, a second doping type may be referred to as a first doping type. The first doping type is different from the second doping type. For example, the first doping type may be P-type and the second doping type may be N-type. Alternatively, the first doping type may be N-type and the second doping type may be P-type.

Spatial relationship terms such as “beneath,” “below,” “lower,” “under,” “above,” “upper,” and the like, may be used herein to describe the relationship between one element or feature and another element or feature as illustrated in the figures. It should be understood that in addition to the orientation shown in the figures, the spatial relationship terms include different orientations of the device in use and operation. For example, if the device in the figures is turned over, elements or features described as “below” or “beneath” or “under” other elements or features would then be oriented “above” the other elements or features. Therefore, the exemplary terms “below” and “beneath” may include two orientations, i.e., above and below. In addition, the device may include other orientations (for example, rotated by 90 degrees or oriented otherwise), and the spatial descriptors used therein are interpreted accordingly.

As used herein, the singular forms “a,” “an,” and “the” may also include the plural forms, unless the context clearly indicates otherwise. It should further be understood that when the terms “comprise/include” or “have”, etc., are used in the description, the presence of the stated features, integers, steps, operations, elements and/or components may be determined, but do not preclude the possibility of the presence or addition of one or more other features, integers, steps, operations, elements, components and/or combinations thereof. Also, as used herein, the term “and/or” includes any and all combinations of the associated listed items.

It should be noted that, the illustration provided in the embodiment is only to illustrate the basic concept of the disclosure in a schematic manner. Although only the components related to this disclosure are shown in the illustrations and not drawn based on the actual quantities, shapes, and sizes of components during practical implementation, the forms, quantities and proportions of components during practical implementation may be arbitrarily modified, and the layouts and forms of the components may also be more complex.

Note that the mutual insulation between the two objects described in the embodiments of the disclosure includes, but is not limited to, the presence of at least one of an insulating material, an insulating air gap or an insulating gap, or the like between the two objects. The direction perpendicular to the substrate described in the embodiments of the disclosure may be a direction perpendicular to a surface (such as the top surface) of the substrate, while the direction parallel to the substrate may be a direction parallel to a surface (such as the top surface) of the substrate.

In the disclosed stacking schemes, the extension direction of the word line is generally perpendicular to the top surface of the substrate, which results in the byte amount of data accessed each time being limited by the number of stacked layers in the storage structure, thereby affecting the bandwidth of the data accessed each time.

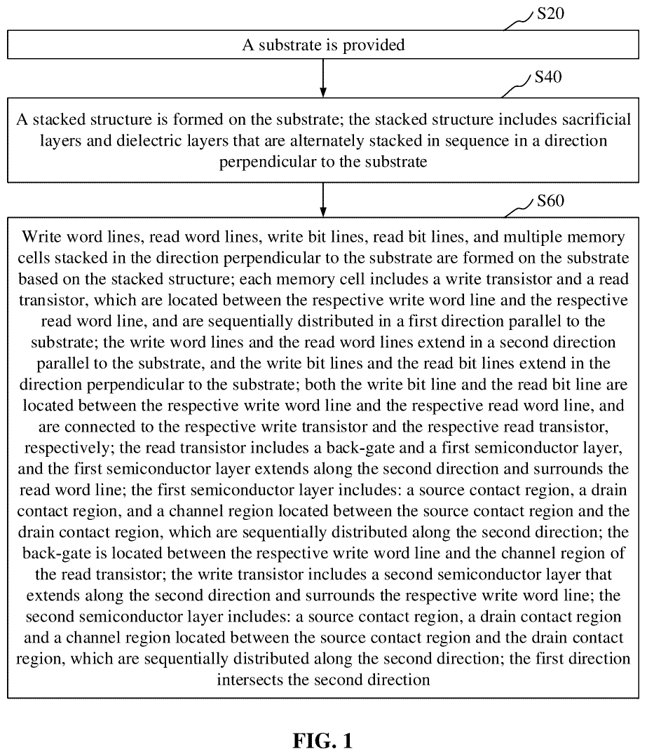

Referring to FIG. 1, in some embodiments of the disclosure, a preparation method for a semiconductor device is provided. The preparation method includes the following operations S20 to S60.

In operation S20, a substrate is provided.

In operation S40, a stacked structure is formed on the substrate. The stacked structure includes sacrificial layers and dielectric layers that are alternately stacked in sequence in a direction perpendicular to the substrate.

In operation S60, write word lines, read word lines, write bit lines, read bit lines, and multiple memory cells stacked in the direction perpendicular to the substrate are formed on the substrate based on the stacked structure. Each memory cell includes a write transistor and a read transistor, which are located between the respective write word line and the respective read word line, and are sequentially distributed in a first direction parallel to the substrate. The write word lines and the read word lines extend in a second direction parallel to the substrate, and the write bit lines and the read bit lines extend in the direction perpendicular to the substrate. Both the write bit line and the read bit line are located between the respective write word line and the respective read word line, and are connected to the respective write transistor and the respective read transistor, respectively. The read transistor includes a back-gate and a first semiconductor layer, and the first semiconductor layer extends along the second direction and surrounds the read word line. The first semiconductor layer includes: a source contact region, a drain contact region, and a channel region located between the source contact region and the drain contact region, which are sequentially distributed along the second direction. The back-gate is located between the respective write word line and the channel region of the read transistor. The write transistor includes a second semiconductor layer that extends along the second direction and surrounds the respective write word line. The second semiconductor layer includes: a source contact region, a drain contact region and a channel region located between the source contact region and the drain contact region, which are sequentially distributed along the second direction. The first direction intersects the second direction.

Specifically, with continued reference to FIG. 1, after forming the stacked structure on the substrate, the stacked structure is patterned to form multiple sub-stacked structures spaced apart from each other in the first direction. Isolation trenches are formed between the sub-stacked structures, and each isolation trench exposes the sacrificial layers and the dielectric layers of the sidewalls of the isolation trench. Multiple memory cells stacked in the direction perpendicular to the substrate are formed on the substrate based on the sub-stack structures. For the memory cells, by disposing the write word lines and the read word lines to be spaced apart from each other in the first direction, and both extend along the second direction parallel to the surface of the substrate; by disposing the source contact region, the drain contact region, and the channel region (located between the source contact region and the drain contact region) of each write transistor, and the source contact region, the drain contact region, and the channel region (located between the source contact region and the drain contact region) of each read transistor to be sequentially distributed along the second direction, herein the write transistor and the read transistor are located between the write word line and the read word line; and by disposing each write bit line and each read bit line (which are located between the respective write word line and the respective read word line to extend along the direction perpendicular to the substrate, this technical solution is quite different from the technical solution in the related art where “both the word lines and the bit lines extend along the direction parallel to the surface of the substrate”, the technical solution of the disclosure facilitates such memory cells to form a memory array with three-dimensional arrangement in the first direction, the second direction, and the thickness direction. Since two columns of memory cells adjacent in the first direction in the memory array can share a common read bit line/a common write bit line, it enables simultaneous access to write word lines or read word lines adjacent in the first direction. Consequently, a memory cell is proposed in which the extension direction of the word lines is parallel to the surface of the substrate, and the extension direction of the bit lines is perpendicular to the surface of the substrate, which overcomes the technical bias that “the number of bytes accessed each time depends on the number of memory cells sharing a single word line”, effectively increasing the bandwidth of the data accessed each time and thereby enhancing the data transmission rate of the prepared product. Moreover, when the write transistor is turned on, this memory cell can provide an electrical signal to the storage node through the write bit line and the write transistor to achieve data writing. It also forms a storage data readout path containing the read word line, the read bit line, and the read transistor, to obtain the relative magnitude of the output electrical signal values through the storage data readout path, and to achieve the readout of the data through the storage data readout path. Therefore, in the embodiments of the disclosure, without relying on a capacitor structure, two transistors are utilized to achieve the writing and reading of stored data. This solution enables a reduction in the volume of the prepared product while ensuring no decrease in storage capacity, which enhances the storage density and integration level of the memory, effectively reduces the process complexity and preparation cost for preparing the memory, and improves the performance and reliability of the prepared memory.

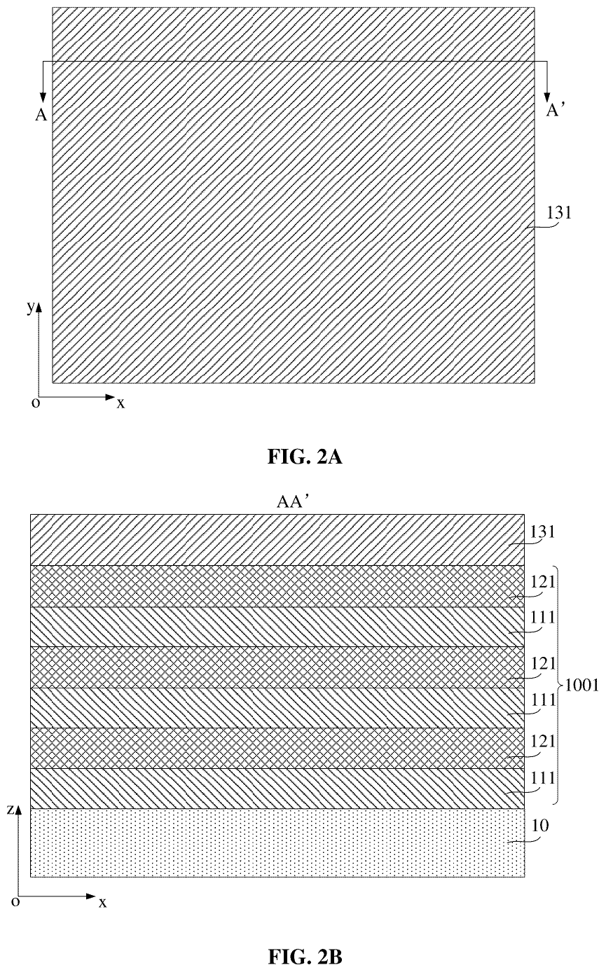

As an example, referring to FIG. 2A to FIG. 2B, the substrate 10 provided in the operation S20 may be composed of semiconductor material, insulating material, conductive material, or any combination thereof. The substrate 10 may be a single-layer structure or a multi-layer structure. For example, the substrate 10 may be, for example, a silicon (Si) substrate, a silicon germanium (SiGe) substrate, a silicon germanium carbon (SiGeC) substrate, a silicon carbide (SiC) substrate, a gallium arsenide (GaAs) substrate, an indium arsenide (InAs) substrate, an indium phosphide (InP) substrate, or another III/V semiconductor substrate or II/VI semiconductor substrate. Alternatively, for another example, the substrate 10 may be a layered substrate including, for example, Si/SiGe, Si/SiC, a silicon-on-insulator (SOI) or a silicon-germanium-on-insulator, etc. Therefore, the scope of protection of the disclosure should not be limited by the type of substrate 10.

The substrate described above may be another structure with a supporting function, such as a peripheral circuit. The multi-layer array of the disclosure is disposed on a supporting structure formed by the peripheral circuit, and the supporting structure may also be understood as the substrate.

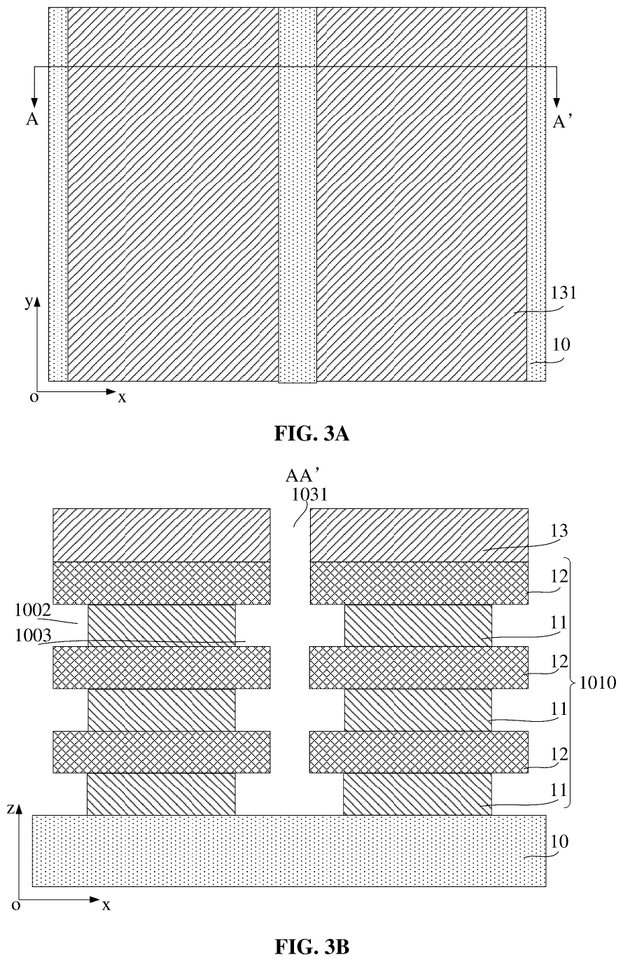

As an example, referring to FIG. 2A to FIG. 3B, in the operation S40, a deposition process and/or an epitaxial growth process may be used to form stacked structures 1001 on the substrate 10. The stacked structure 1001 includes sacrificial material layers 111 and dielectric material layers 121 sequentially stacked in the thickness direction (e.g., oz direction) of the substrate 10. In some embodiments, the sacrificial material layer 111 may be adjacent to the substrate 10. Then, a first mask layer 131 is formed on the top surface of the top dielectric material layer 121. After patterning the first mask layer 131, a first patterned mask layer 13 with first opening patterns (not shown) is formed. The first opening pattern is used to define the shape and position of the isolation trench 1031. Then, using the first patterned mask layer 13 as a mask, the sacrificial material layers 111 and the dielectric material layers 121 that are stacked are etched in the oz direction to form the isolation trenches 1031 that each exposes a portion of the substrate 10. The remaining sacrificial material layers 111 are used to form the sacrificial layers 11, and the remaining dielectric material layers 121 are used to form the dielectric layers 12. The sacrificial layers 11 and the dielectric layers alternately stacked in sequence in the oz direction constitute sub-stacked structures 1010. Each isolation trench 1031 is located between two sub-stacked structures 1010, and each sub-stacked structure has two isolation trenches 1031. FIG. 3B illustrates two sub-stacked structures 1010, and a total of three isolation trenches 1031 are embodied.

The material of the sacrificial layer 11 may be a semiconductor material or a conductive material. The semiconductor material may be silicon germanium (SiGe). The conductive material may be a conductive metal, a metal silicide, or the like. The material of the dielectric layer 12 may be selected from electrically insulating materials such as silicon dioxide, silicon oxynitride, silicon nitride carbide, and combinations thereof. The first mask layer 131 may be a hard mask layer. The deposition process may include, but is not limited to, at least one of: a chemical vapor deposition (CVD) process, an atomic layer deposition (ALD) process, a high density plasma (HDP) process, a plasma-enhanced deposition process, or a spin-on dielectric (SOD) process. The etching process may include, but is not limited to, a dry etching process and/or a wet etching process. The dry etching process may include, but is not limited to, at least one of: a reactive ion etching (RIE), an inductively coupled plasma etching (ICP), or a high density plasma etching (HDP). In some embodiments, during subsequent process operations, the first patterned mask layer 13 may be retained to protect the dielectric layer 12 directly below it, preventing damage to the dielectric layer 12 in the subsequent processes. In some other embodiments, during the subsequent process operations, the first patterned mask layer 13 may be removed first to meet the actual demands of various different application scenarios.

As an example, referring to FIG. 3A to FIG. 5B, isolation trenches 1031 extending along the oy direction and penetrating through the stacked structures 1001 are formed between the sub-stacked structures 1010 adjacent in the ox direction. The two isolation trenches 1031 adjacent in the ox direction expose the sacrificial layers 11 and the dielectric layers 12 on two opposite sidewalls. The exposed sacrificial layers 11 and dielectric layers 12 on the two opposite sidewalls belong to one sub-stacked structure 1010. In the operation S60, the operation that multiple memory cells stacked in the direction perpendicular to the substrate 10 are formed on the substrate 10 based on the sub-stack structures 1010, includes the following operations S612, S614 and S616.

In operation S612: the exposed sacrificial layers 11 are etched back through the two isolation trenches 1031 adjacent in the ox direction. For example, the opposite side walls of each sacrificial layer 11 in the ox direction are etched back, to form a first accommodating groove 1002 and a second accommodating groove 1003, which are located on two opposite side walls of one sub-stacked structure 1010, respectively.

In operation S614, by depositing film layers in each of the isolation trenches 1031, an initial semiconductor layer 1004, a gate dielectric layer 22 and a word line material layer 211 are sequentially formed on inner walls of the first accommodating grooves 1002 and are sequentially formed on inner walls of the second accommodating grooves 1003. The word line material layer 211 located in each of the first accommodating grooves 1002 is used to form respective write word lines 20, and the word line material layer 211 located in each of second accommodating grooves 1003 is used to form the respective read word lines 30.

In operation S616, a portion of the initial semiconductor layer 1004, a portion of the gate dielectric layer 22 and a portion of the word line material layer 211 that are located within the isolation trench 1031 are removed, so that semiconductor layers and word lines of two memory cells adjacent in the ox direction are disconnected, to form initial first semiconductor layers that are disconnected from each other across different layers, initial second semiconductor layers that are disconnected from each other across different layers, read word lines that are disconnected from each other across different layers, and write word lines that are disconnected from each other across different layers.

In this operation, independent semiconductor layers and word lines have been formed, and how to form them will be described as follows.

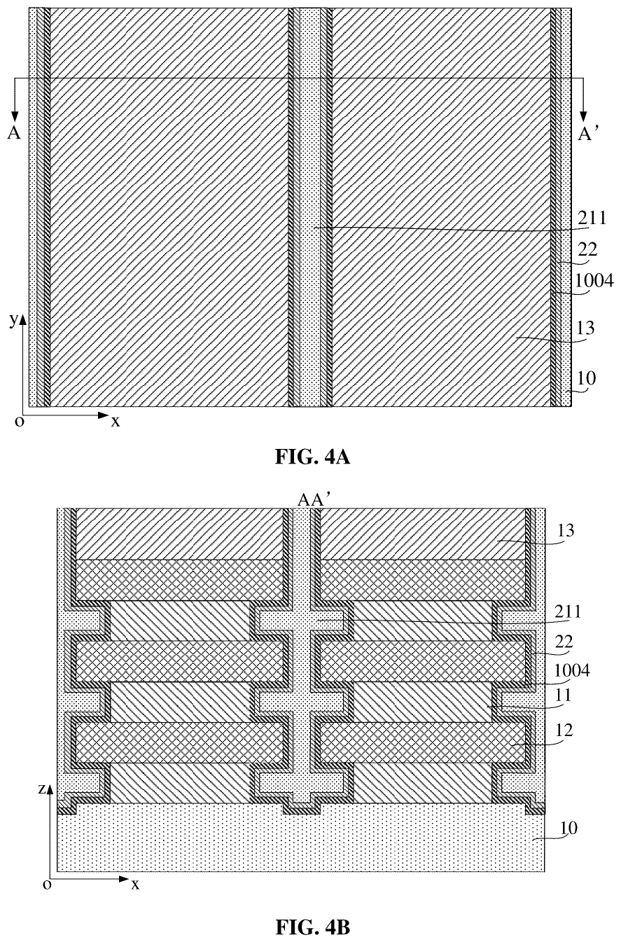

As an example, with continued reference to FIG. 4A to FIG. 4B, in the operation S614, an atomic layer deposition process may be used to form the initial semiconductor layer 1004 on the inner walls of the first accommodating grooves 1002 in the isolation trench 1031 and the initial semiconductor layer 1004 on the inner walls of the second accommodating grooves 1003 in the isolation trench 1031. This process allows precise control of the film thickness of the initial semiconductor layer 1004, which is beneficial for optimizing film-forming process of the initial semiconductor layer 1004 and improving the uniformity and density of the formed initial semiconductor layer 1004, thereby optimizing the performance of the semiconductor device. The material of the initial semiconductor layer 1004 may be selected from: indium gallium zinc oxide, indium zinc oxide, transition metal, transition metal oxide, and combinations thereof. In this embodiment, the material of the initial semiconductor layer 1004 is a metal oxide semiconductor material, and the material of the metal oxide may be indium gallium zinc oxide (IGZO). When the material of the metal oxide is IGZO, the leakage current of the transistor is relatively small (the leakage current is less than or equal to 10⁻¹⁵ A), thereby ensuring a low refresh rate of the dynamic memory. It should be noted that, the material of the metal oxide may also be ITO, IWO, ZnOₓ, InOₓ, In₂O₃, InWO, SnO₂, TiOₓ, InSnOₓ, ZnₓO_{y}N_{z}, MgₓZn_{y}O_{z}, InₓZn_{y}O_{z}, InₓGa_{y}Zn_{z}Oₐ, ZrₓIn_{y}Zn_{z}Oₐ, HfₓIn_{y}Zn_{z}Oₐ, SnₓIn_{y}Zn_{z}Oₐ, AlₓSn_{y}In_{z}ZnₐO_{d}, SiₓIn_{y}Zn_{z}Oₐ, ZnₓSn_{y}O_{z}, AlₓZn_{y}Sn_{z}Oₐ, GaₓZn_{y}Sn_{z}Oₐ, ZrₓZn_{y}Sn_{z}Oₐ, InGaSiO and other materials, as long as the leakage current of the transistor can meet the requirements, specific materials may be adjusted according to the actual situations.

In the operation S614, the gate dielectric layer 22 may be formed on the outer surface of the initial semiconductor layer 1004 in the first accommodating groove 1002 and formed on the outer surface of the initial semiconductor layer 1004 in the second accommodating groove 1003 by using at least one of: an in-situ steam generation (ISSG) process, an atomic layer deposition process, a plasma vapor deposition process, or a rapid thermal oxidation (RTO) process. The material of the gate dielectric layer 22 may be selected from silicon dioxide (SiO₂), silicon oxynitride (SiON), silicon nitride, aluminum oxide (Al₂O₃), aluminum oxynitride (AION), and combinations thereof. The gate dielectric layer 22 may also be a high-k dielectric material (a dielectric material with a dielectric coefficient greater than or equal to 3.9), or a low-k dielectric material (a dielectric coefficient greater than or equal to 2.5 and less than 3.9), an ultra-low-k dielectric material (a dielectric coefficient less than 2.5), a ferroelectric material, a antiferroelectric material, silicon carbide (SiC), or any combination thereof. In the operation S614, a deposition process may be used to form the word line material layer 211 that at least fills each of the isolation trenches 1031. And then, the top surface of the word line material layer 211 may be processed by using at least one of: a planarization process, a planar push process, an etching process, or a chemical mechanical polishing process, so that the top surface of the word line material layer 211 is flush with the top surface of the sub-stacked structure 1010. The deposition process may include, but is not limited to, at least one of processes such as CVD, ALD, HDP, or SOD. The material of the word line material layer 211 is selected from: indium tin oxide, polysilicon, copper, tungsten, aluminum, copper alloys, titanium, titanium nitride, niobium nitride, tantalum nitride, and combinations thereof.

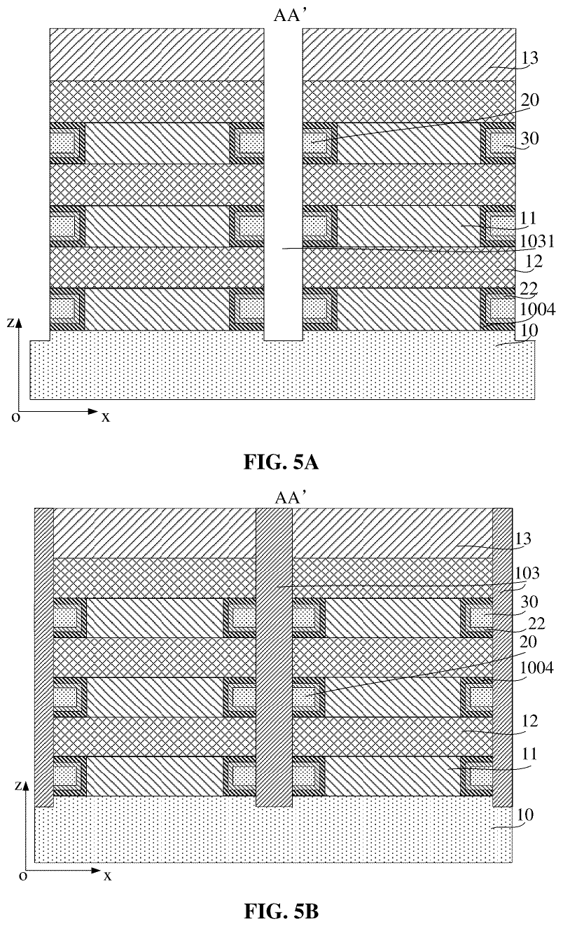

As an example, with continued reference to FIG. 5A to FIG. 5B, in the operation S614, a dry etching process may be used to etch each of the sub-stacked structures 1010 in the oz direction, to remove a portion of the word line material layer 211, a portion of the gate dielectric layer 22 and a portion of the initial semiconductor layer 1004 that are located in each of the isolation trenches 1031. The word line material layer 211 located in the first accommodating groove 1002 is used to form the write word line 20, and the word line material layer 211 located in the second accommodating groove 1003 is used to form the read word line 30. The isolation structure 103 is then filled in the isolation trench 1031, so that the write word line 20 and the read word line 30 between the two memory cells adjacent in the ox direction are insulated from each other through the isolation structure 103 therebetween, the two memory cells adjacent in the oz direction are insulated from each other through the dielectric layer 12 therebetween, and the two memory cells adjacent in the ox direction are insulated from each other through the isolation structure 103 therebetween. The top surfaces of the isolation structures 103 may then be processed by using at least one of: a planarization process, a planar push process, an etching process, or a chemical mechanical polishing process, so that the top surfaces of the isolation structures 103 are flush with the top surfaces of the sub-stacked structures 1010.

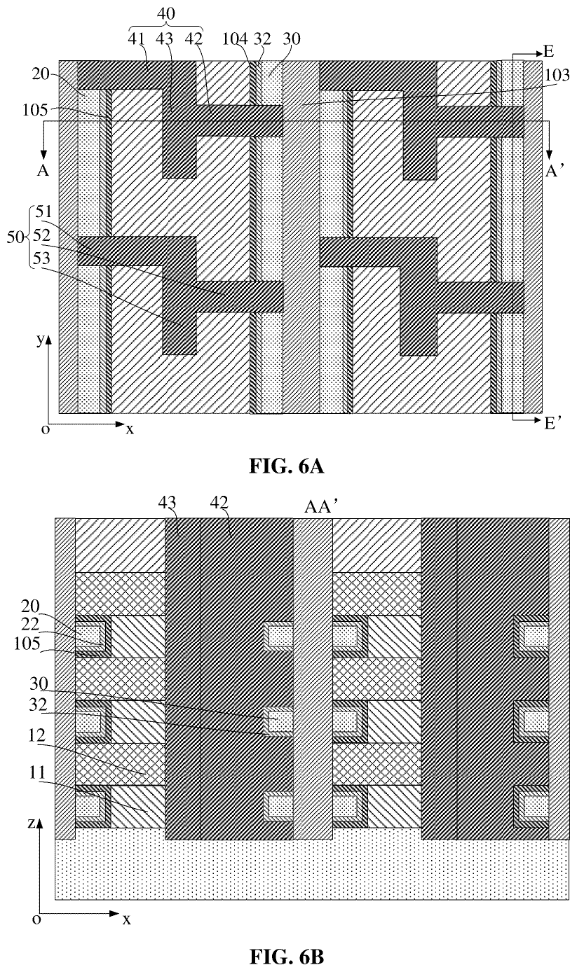

As an example, referring to FIG. 6A to FIG. 6C, after forming the write word lines 20 and the read word lines 30, the preparation method further includes operations S622 and S624.

In operation S622: a first trench and a second trench, which extend along the first direction and are spaced apart from each other along second direction, are formed in the sub-stacked structure 1010. The first trench may disconnect the first semiconductor layer and the second semiconductor layer, which are connected to one word line through the gate insulating layer. Both the first trench and the second trench expose a portion of the substrate 10, and a portion of the outer surface of the gate dielectric layer 22 close to the sacrificial layer 11, to disconnect the second semiconductor layers between different memory cells connected through the same write word line and the first semiconductor layers between different memory cells connected through the same read word line. In operation S624, the first trench and the second trench are filled with an insulating layer to form a first insulating structure 40 in the first trench and a second insulating structure 50 in the second trench.

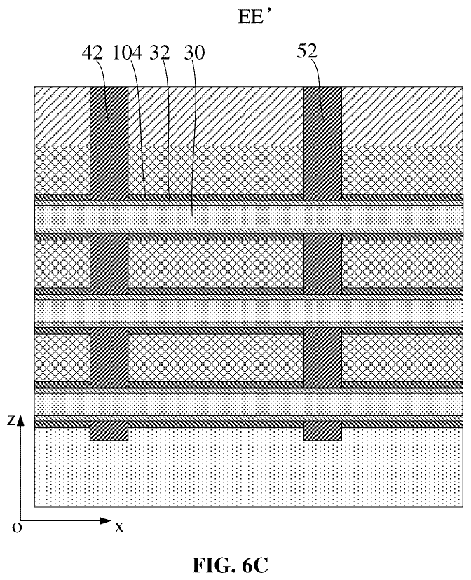

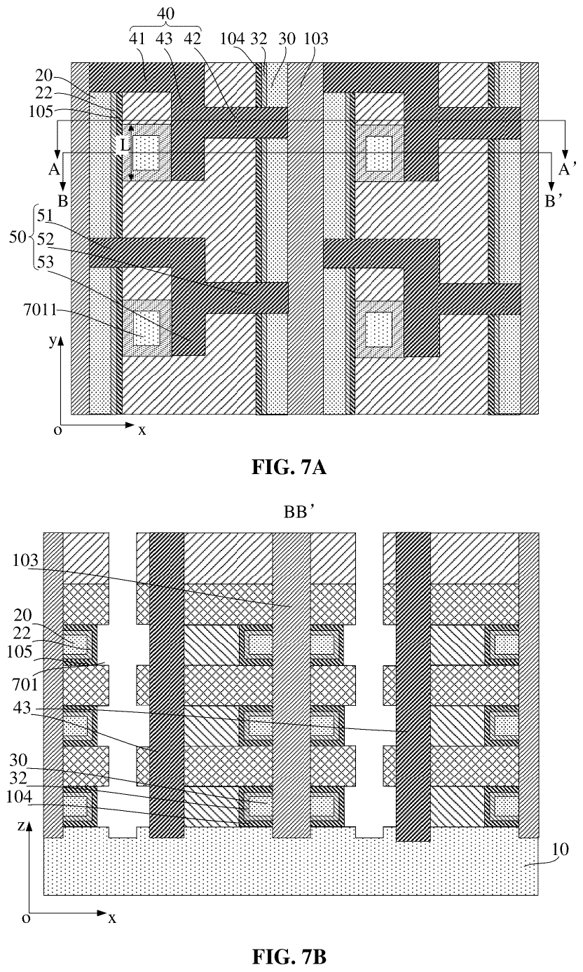

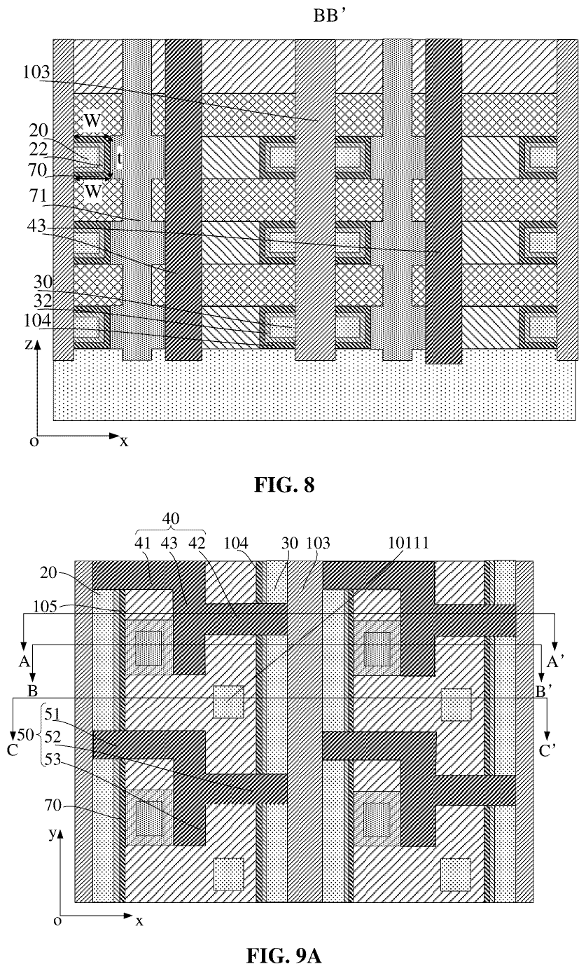

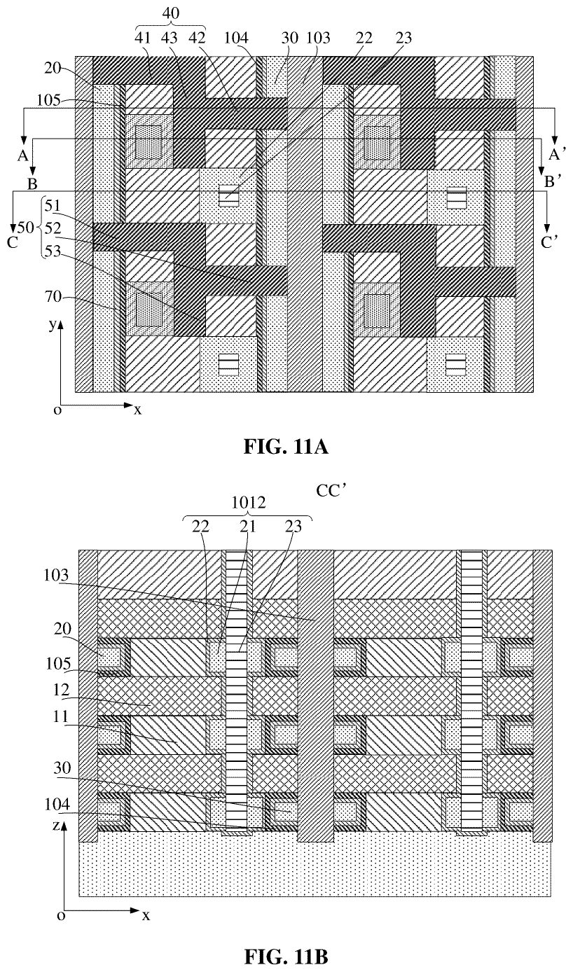

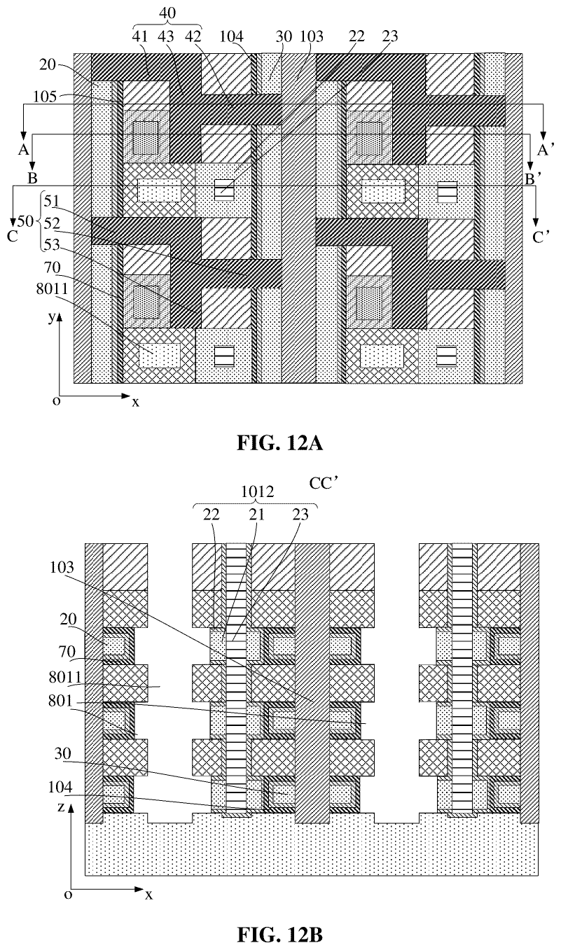

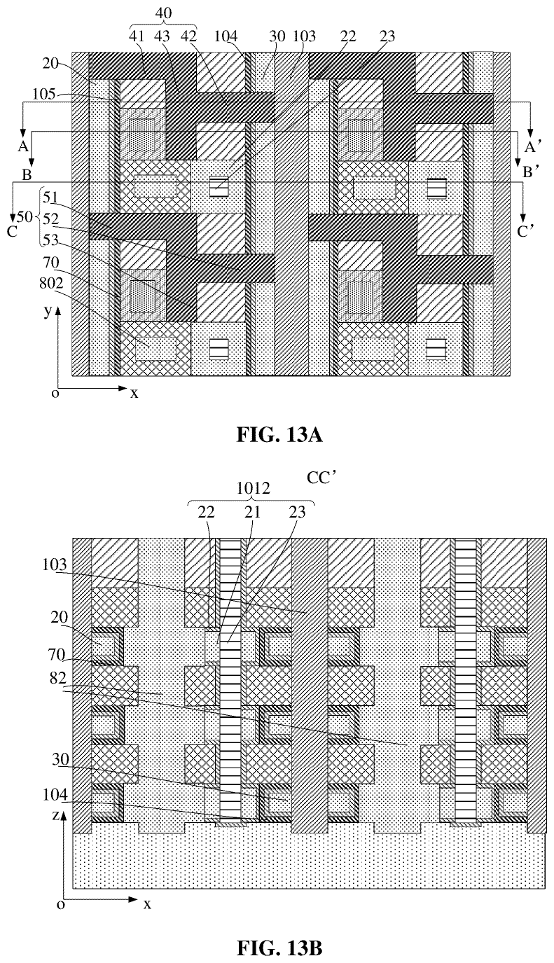

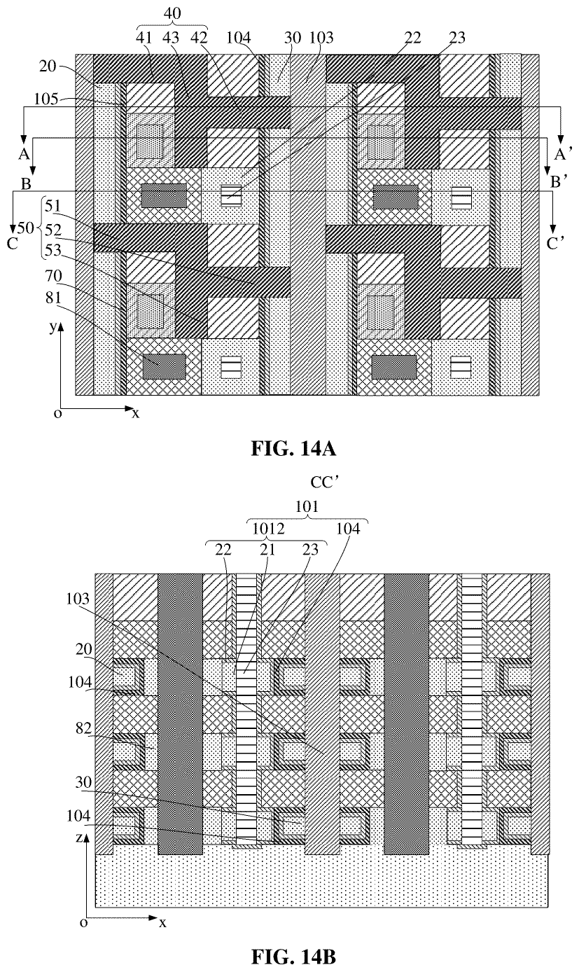

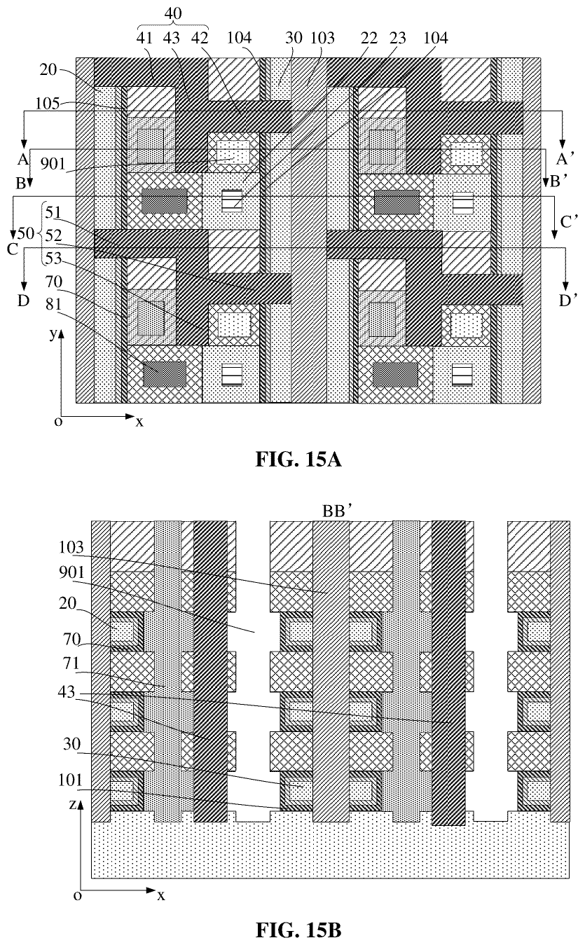

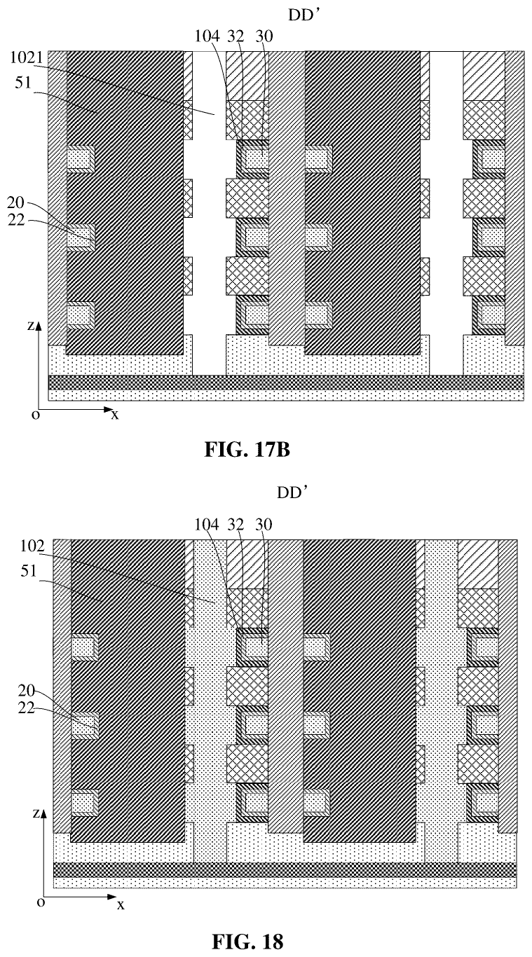

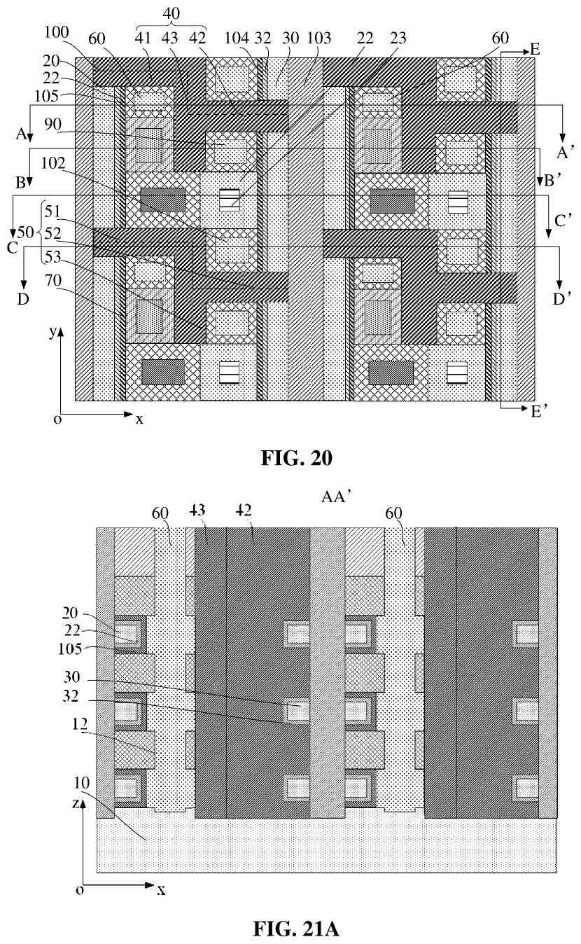

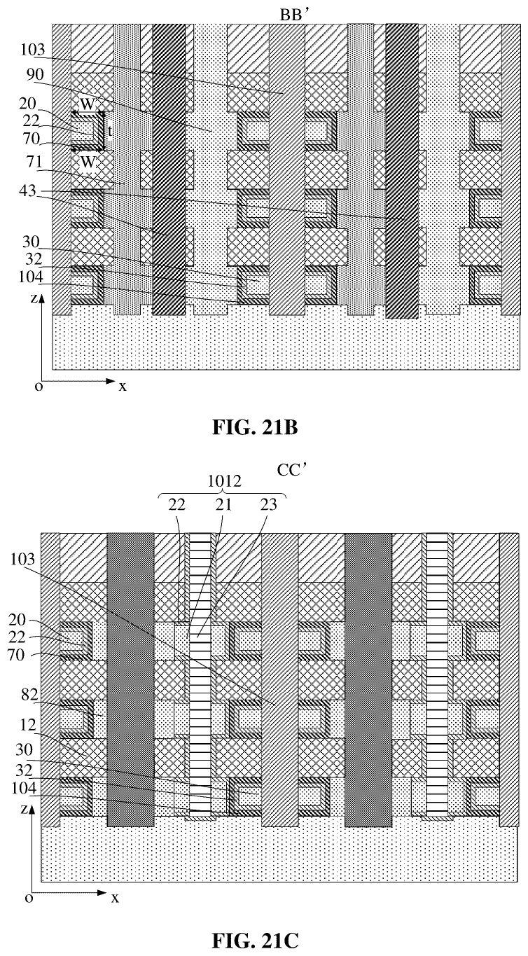

As an example, with continued reference to FIG. 6A, FIG. 7A, FIG. 8, FIG. 9A, FIG. 11A, FIG. 12A, FIG. 13A, FIG. 14A, FIG. 15A, FIG. 17A, FIG. 19A, and FIG. 20, in the top-view schematic diagram illustrated in FIG. 6A, in order to show the specific structures of the write word line 20 and the read word line 30, the dielectric layer 12 and the first patterned mask layer 13, which are directly above the write word line 20 and the read word line 30, are partially transparentized, so that the write word lines 20 and the read word lines 30 directly below the dielectric layer 12 and the write word lines 20 and the read word lines 30 directly below the first patterned mask layer 13 can be seen. For example, in order to show the key structural features of the covered film layer(s) in the subsequent drawings, the method of partially transparentizing the upper film layer(s) thereof will not be repeated.

As an example, with continued reference to FIG. 6A to FIG. 6C, in the operation S624, an etching process may be used to form, in the sub-stacked structure 1010, a first trench (not shown) for filling the first insulating structure 40 and a second trench (not shown) for forming the second insulating structure 50. The first trench and the second trench are used to define the shape and position of a single memory cell; and both the first trench and the second trench expose a portion of the substrate 10 and a portion of the outer surface of the gate dielectric layer 22 close to the sacrificial layer 11. The outer surface of the gate dielectric layer 22 exposed by the first trench and exposed by the second trench includes an upper surface, a lower surface, and a side surface. The gate dielectric layer within the first trench and the gate dielectric layer within the second trench are fully exposed, ensuring that the initial semiconductor layer 1004 at these locations are completely removed.

The continuously distributed initial semiconductor layer 1004 surrounding the write word lines 20 and the read word lines 30 is disconnected to form first semiconductor layers 104 and second semiconductor layers 105 independent of each other. In the operation S622, a portion of the initial semiconductor layer 1004 is removed in the process of forming the first trench and the second trench by etching, to allow the outer surface of the gate dielectric layer 22 including the upper surface, the lower surface and the side surface are exposed by the first trench and the second trench, so that the initial semiconductor layer 1004 is disconnected by the first trench and the second trench. After forming the first insulating structure 40 in the first trench and forming the second insulating structure 50 in the second trench, first semiconductor layers 104 adjacent in the oy direction are insulated from each other by the first insulating structure 40 or the second insulating structure 50, and second semiconductor layers 105 adjacent in the oy direction are insulated from each other by the first insulating structure 40 or the second insulating structure 50, which ensures the independence, operational stability, and reliability of each “2TOC” memory cell relative to the external environment, effectively reduces the complexity of forming a three-dimensional stacked structure based on the “2TOC” memory cell, and increases the storage density per unit volume of the three-dimensional stacked structure.

As an example, with continued reference to FIG. 6A to FIG. 6C, in the operation S622, in the process of forming the first trench and the second trench by etching, the gate dielectric layer 22 is used as an etching stop layer to define the length of the first trench and the length of the second trench along the ox direction. The length of the first trench and the length of the second trench along the oy direction may be defined by controlling the etching rate and time, thereby defining the length of a single memory cell in the oy direction based on the spacing between the first trench and the second trench in the oy direction. In the operation S624, by using the deposition process, the first insulating structure 40 may be formed in the first trench, and the second insulating structure 50 may be formed in the second trench. The material of the first insulating structure 40 is selected from silicon oxide, silicon nitride, silicon oxynitride, silicon nitride carbide, and combinations thereof. The material of the second insulating structure 50 is selected from silicon oxide, silicon nitride, silicon oxynitride, silicon nitride carbide, and combinations thereof. The material of the first insulating structure 40 may be the same as the material of the second insulating structure 50. The first trench and the second trench may be connected, and at this time, the first insulating structure 40 and the second insulating structure 50 may be filled through a one process.

Although the shapes and volumes of the first insulating structure 40 and the second insulating structure 50 in the drawings of the disclosure are substantially the same, the shapes and volumes of the first insulating structure 40 and the second insulating structure 50 may be different, and the shapes and volumes of the first insulating structure 40 and the second insulating structure 50 are not limited to those shown in the drawings. The first insulating structure 40 and the second insulating structure 50 are used to jointly define the shape and volume of a single memory cell, thereby enabling a more compact layout and a smaller volume of the single memory cell. Under the same or similar inventive concept as in the disclosure, identical/equivalent variations made to the shape and volume of the first insulating structure 40 and/or the shape and volume of the second insulating structure 50 shall fall within the scope of protection of the disclosure.

Note that, for the sake of brevity in the specification, in the structural schematic diagrams provided in the subsequent embodiments, unless a corresponding schematic diagram of a cross-sectional structure is separately provided, structural schematic diagrams of different perspectives of structures related to the inventive concept of the embodiments of the disclosure may be cross-referenced.

As an example, with continued reference to FIG. 6A to FIG. 6C, the first insulating structure 40 includes a first horizontal portion 41 and a second horizontal portion 42 that extend along the first direction (e.g., the ox direction), and a first vertical portion 43 that extends along the second direction (e.g., the oy direction). The first vertical portion 43 has a first end and a second end that opposite to each other in the oy direction. The first end of the first vertical portion 43 is connected to an end of the first horizontal portion 41 that faces away from the write word line 20 in the ox direction, to form a bent portion. The first vertical portion 43 is used to isolate the write transistor from the read bit line, which will be subsequently formed on the opposite sides of the first vertical portion 43 in the ox direction.

As an example, with continued reference to FIG. 6A to FIG. 6C, the second insulating structure 50 includes a third horizontal portion 51 and a fourth horizontal portion 52 that extend along the first direction (e.g., the ox direction), and a second vertical portion 53 that extends along the second direction (e.g., the oy direction). The second vertical portion 53 has a first end and a second end that opposite to each other in the oy direction. The first end of the second vertical portion 53 is connected to an end of the third horizontal portion 51 that faces away from the write word line 20 in the ox direction, to form a bent portion. The second end of the second vertical portion 53 is connected to an end of the fourth horizontal portion 52 that faces away from the read word line 30 in the ox direction, to form a bent portion. In this way, the write bit line 60, the write transistor 70, the read bit line 90, the read transistor 101, and the reference line 102 are all located in a region surrounded by the write word line 20 and the read word line 30 (which are spaced apart from each other in the ox direction), together with the first insulating structures 40 and the second insulating structures 50 (which are spaced apart from each other in the oy direction), which ensures the independence, operational stability, and reliability of each “2TOC” memory cell relative to the external environment, effectively reduces the complexity of forming a three-dimensional stacked structure based on the “2TOC” memory cell, and increases the storage density per unit volume of the three-dimensional stacked structure.

As an example, referring to FIG. 7A to FIG. 8, the first insulating structure 40 extends from the gate dielectric layer of the write transistor 70 to the gate dielectric layer of the read transistor 101, for simultaneously disconnecting the semiconductor layers of the two transistors between adjacent memory cells of one word line. The first insulating structure 40 has a bent portion extending along the second direction (e.g., the oy direction). The second semiconductor layer 105 has two opposite main surfaces that are a first side and a second side of the second semiconductor layer 105, respectively. The first side of the second semiconductor layer 105 faces away from the write word line 20, and the second side of the second semiconductor layer 105 faces towards the write word line 20. The second semiconductor layer 105 includes a source contact region of the write transistor 70, a drain contact region of the write transistor 70, and a channel region located between the source contact region and the drain contact region, which are spaced apart from each other on the first side. After forming the first insulating structure 40 and the second insulating structure 50 in the operation S624, the preparation method further includes operations S632, S634 and S636.

In operation S632, the sub-stacked structure 1010 is etched in the direction (e.g., the oz direction) perpendicular to the substrate, to obtain a first sub-via 7011 that exposes a portion of the substrate 10 and is located in the region surrounded by the first insulating structure 40 and the write word line 20.

In operation S634, the sacrificial layer 11 is etched in the first direction and the second direction through the first sub-via 7011, to obtain a first accommodating recess 701 for defining a channel length of the write transistor 70. A portion of side surface of the second semiconductor layer 105 that is exposed by the first accommodating recess 701 is used to form the channel region of the write transistor 70.

In operation S636, an isolation layer 71 is formed in the first accommodating recesses 701, to form write transistors 70 that are insulated from each other in the direction perpendicular to the substrate.

As an example, referring to FIG. 7A to FIG. 8, in the operation S632, a dry etching process may be used to etch the sub-stacked structure 1010 in the oz direction, to obtain the first sub-via 7011 that exposes a portion of the substrate 10 and is located between the first vertical portion 43 and the write word line 20. In the operation S634, a dry etching process and/or a wet etching process may be used to etch the sacrificial layer 11 in the first direction (e.g., the ox direction) and the second direction (e.g., the oy direction) through the first sub-via 7011. The second semiconductor layer 105 is used as an etching stop layer, so that the first accommodating recess 701 that exposes a portion of the side surface of the second semiconductor layer 105 is obtained. The portion of the side surface of the second semiconductor layer 105 that is exposed by the first accommodating recess 701 is used to form the channel region of the write transistor 70. The length of the first accommodating recess 701 in the oy direction is used to define the channel length of the write transistor 70. Subsequently, a deposition process may be used to form an isolation layer 71 in the first accommodating recess 701 and the first sub-via 7011, to form the write transistors 70 insulated from each other in the oz direction. Then, the top surface of the isolation layer 71 are planarized to form the isolation layer 71 with a top surface that is flush with the top surface of the sub-stacked structure 1010. The material of the isolation layer 71 may be selected from silicon oxide, silicon nitride, silicon oxynitride, silicon nitride carbide, and combinations thereof. Due to the fact that one main surface of the second semiconductor layer 105 for forming the write transistor 70 covers at least a portion of the upper surface, at least a portion of the lower surface, and at least a portion of the side surface of the write word line 20, and the fact that the source contact region of the write transistor 70, the drain contact region of the write transistor 70, and the channel region located between the source contact region and the drain contact region are formed on another main surface of the second semiconductor layer 105, the gate length of the write transistor 70 is L and the gate width of the write transistor 70 is t+2 W, which effectively increases the gate width without increasing the volume of the write transistor 70, thereby significantly improving the performance of the write transistor 70. Furthermore, due to the fact that the initial semiconductor layer for forming the second semiconductor layer 105 is formed on the surface of the write word line 20 during the preparation process of the write word line 20, the process complexity and cost of preparing the write transistor 70 are effectively reduced.

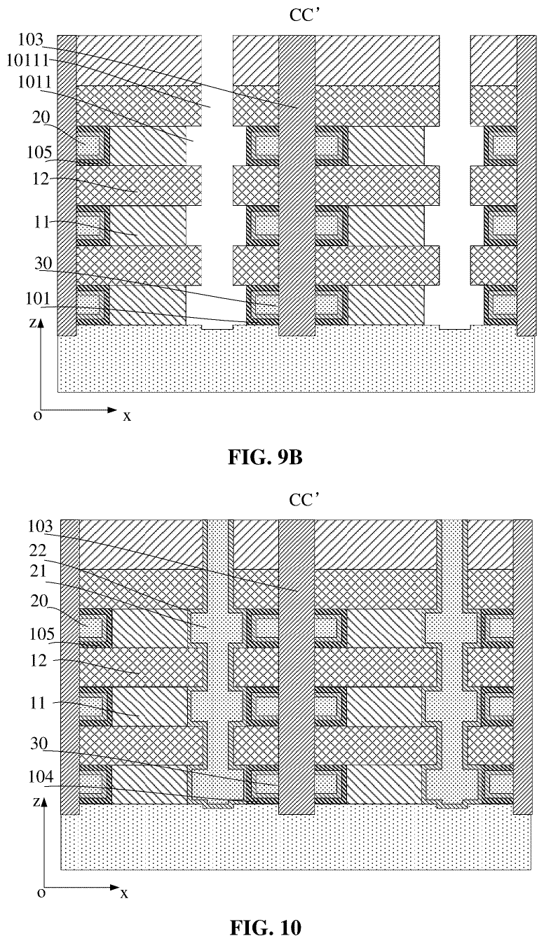

As an example, referring to FIG. 9A to FIG. 11B, the first semiconductor layer 104 has two opposite main surfaces that are a first side and a second side of the first semiconductor layer 104, respectively. The first side of the first semiconductor layer 104 faces away from the read word line 30, and the second side of the first semiconductor layer 104 faces toward the read word line 30. The first semiconductor layer 104 includes a source contact region of the read transistor 101, a drain contact region of the read transistor 101, and a channel region located between the source contact region and the drain contact region, which are spaced apart from each other on the first side. After forming the isolation layer in the first accommodating recess 701 in the operation S636, the preparation method further includes operations S642, S644, S646 and S648.

In operation S642, the sub-stacked structure 1010 is etched in the direction (e.g., the oz direction) perpendicular to the substrate, to obtain a second sub-via 10111 that exposes a portion of the substrate 10 and is located between the bent portion of the first insulating structure 40 and the first semiconductor layer 104.

In operation S644, the sacrificial layer 11 is etched in the first direction and the second direction through the second sub-via 10111, to obtain a second accommodating recess 1011 for defining a channel length of the read transistor 101. A portion of a side surface of the first semiconductor layer 104 that is exposed by the second accommodating recess 1011 is used to form the channel region of the read transistor 101.

In operation S646, a gate dielectric layer 22 and a gate conductive layer 21 are sequentially formed in the second accommodating recesses 1011, to obtain the second sub-via 10111. The gate dielectric layer 22 covers an inner wall of the second sub-via 10111.

In operation S648, an insulating layer 23 is formed in the second sub-via 10111, to form back-gates 1012 that are insulated from each other in the direction perpendicular to the substrate. The insulating layer 23, the gate conductive layer 21 and the gate dielectric layer 22 are used to jointly form the back-gate.

As an example, referring to FIG. 9A to FIG. 11B, in the operation S642, a dry etching process may be used to etch the sub-stacked structure 1010 in the oz direction, to obtain the second sub-via 10111 that exposes a portion of the substrate 10 and is located between the second end of the first vertical portion 43 and the read word line 30. In the operation S644, a dry etching process and/or a wet etching process may be used to etch the sacrificial layer 11 in the first direction (e.g., the ox direction) and the second direction (e.g., the oy direction) through the second sub-via 10111, to obtain the second accommodating recess 1011 that exposes a portion of the side surface of the first semiconductor layer 104. The portion of the side surface of the first semiconductor layer 104 that is exposed by the second accommodating recess 1011 is used to form the channel region of the read transistor 101. The length of the second accommodating recess 1011 in the oy direction is used to define the channel length of the read transistor 101. The second sub-via 10111 and the second accommodating recesses 1011 are used to jointly form the first via. In the operation S646, the gate dielectric layer 22 may be formed on the inner surfaces of the second accommodating recesses 1011 by using at least one of: an in-situ steam generation (ISSG) process, an atomic layer deposition process, a plasma vapor deposition process, or a rapid thermal oxidation (RTO) process. In the operation S646, a deposition process may be used to form the gate conductive layer 21 filling at least the second accommodating recesses 1011 and the second sub-via 10111 in the second accommodating recess 1011; and then a portion (located in the second sub-via 10111) of the gate conductive layer 21 may be etched and removed in the oz direction. In the operation S648, a deposition process may be used to form the insulating layer 23 in the second sub-via 10111, to form the back-gates 1012 insulated from each other in the oz direction. The insulating layer 23, the gate conductive layer 21 and the gate dielectric layer 22 are used to jointly form the back-gate 1012. Since the preparation of different read transistors 101 in the stacked structure is simultaneously completed in the same process operation, the complexity of the process preparation is effectively reduced. Since the gate dielectric layer 22 of the back-gate 1012 circumferentially surrounds the gate conductive layer 21 of the back-gate 1012, the on-resistance of the read transistor 101 can be reduced without compromising the performance of the read transistor 101. Furthermore, the side surface of the back-gate 1012 close to the write word line 20 in the ox direction can be electrically connected to the storage node (SN), while the side surface of the back-gate 1012 close to the read word line 30 in the ox direction is used to electrically connect to the channel region of the read transistor 101. The side surface of the back-gate 1012 close to the first insulating structure 40 in the oy direction is used to electrically connect to the read bit line 90, while the side surface of the back-gate 1012 close to the second insulating structure 50 in the oy direction is used to electrically connect to the reference line 102, which effectively reduces the volume of the “2TOC” memory cell.

As an example, referring to FIG. 12A to FIG. 14B, in the operation S648, after forming the insulating layer 23 in the second sub-via 10111, the preparation method further includes operations S652, S654, S656 and S658.

In operation S652, the sub-stacked structure 1010 is etched in the direction perpendicular to the substrate, to obtain a third sub-via 8011 that exposes a portion of the substrate 10 and is located in the region surrounded by the second insulating structure 50, the back-gate 1012, the first insulating structure 40 and the second semiconductor layer 105 together.

In operation S654, the sacrificial layer 11 is etched in the first direction and the second direction through the third sub-via 8011, to obtain a third accommodating recess 801 that exposes the source contact region of the write transistor 70 and the gate conductive layer 21 of the back-gate 1012.

In operation S656, a conductive layer 82 is formed in the third accommodating recesses 801 to obtain the third sub-via 8011.

In operation S658, an insulating layer is formed in the third sub-via 8011.

As an example, referring to FIG. 12A to FIG. 14B, in the top-view schematic diagram illustrated in FIG. 14A, the film layers directly above the top gate dielectric layer 22 are partially transparentized, to illustrate the shape and position of the back-gate 1012 in the top-view schematic diagram. In the operation S652, a dry etching process may be used to etch the sub-stacked structure 1010 in the oz direction, to obtain the third sub-via 8011 that exposes a portion of the substrate 10, is located between the second end of the first vertical portion 43 and the third horizontal portion 51, and is located between the read transistor 101 and the write word line 20. In the operation S654, a dry etching process and/or a wet etching process may be used to etch the sacrificial layer 11 in the ox direction and the oy direction through the third sub-via 8011, to obtain the third accommodating recess 801 that exposes the source contact region of the write transistor 70 and the gate conductive layer 21 of the back-gate 1012. The third sub-via 8011 and the third accommodating recesses 801 are used to jointly form a second via. In the operation S656, a deposition process may be used to form the conductive layer 82 in the third accommodating recesses 801 and the third sub-via 8011. And then, the top surface of the conductive layer 82 is planarized to obtain the conductive layer 82 with the top surface that is flush with the top surface of the sub-stack structure 1010. In the operation S656, a dry etching process may be used to etch along the oz direction and remove a portion of the conductive layer 82 that is located in the third sub-via 8011. In the operation S658, a deposition process may be used to form an insulating layer in the third sub-via 8011, to form storage nodes insulated from each other in the oz direction. The equipotential point between the source contact region of the write transistor 70 and the back-gate 1012 is used to collectively form a storage node (SN). The material of the conductive layer 82 may be selected from doped polysilicon, copper, tungsten, aluminum, copper alloys, and combinations thereof. The material of the insulating layer may be selected from silicon oxide, silicon nitride, silicon oxynitride, silicon nitride carbide, and combinations thereof. The channel region of the read transistor 101, the first via, the second via and the source contact region of the write transistor 70 all cover at least one straight line parallel to the ox direction, to reduce the volume of the “2TOC” memory cell.

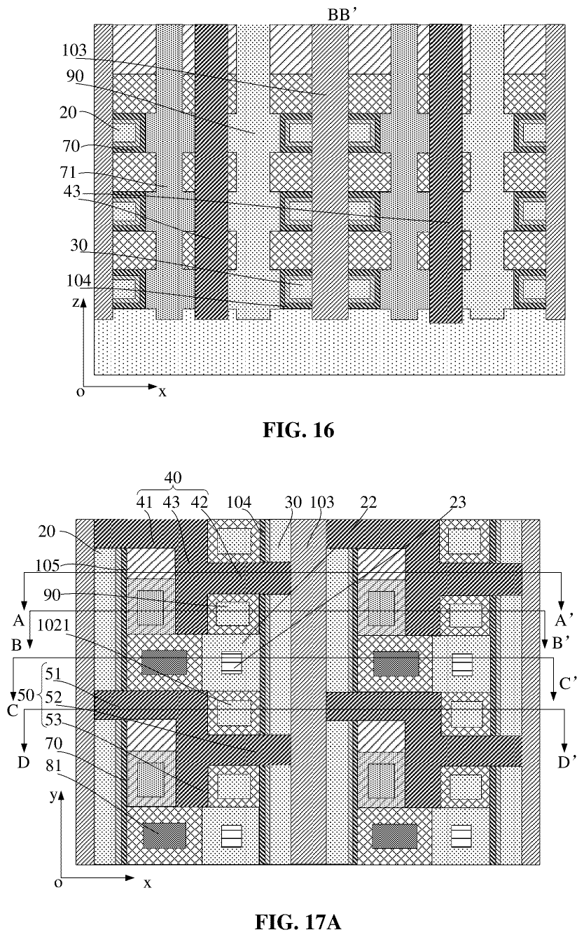

As an example, referring to FIG. 15A to FIG. 16, in the operation S60, the operation that multiple memory cells stacked in the direction perpendicular to the substrate are formed on the substrate based on the stacked structure may include the following operations S662 and S664.

In operation S662, a fifth sub-via 901 is formed in a region surrounded by the bent portion of the first insulating structure 40 and the first semiconductor layer 104. The fifth sub-via exposes the drain contact region of the read transistor 101.

In operation S664, the read bit line 90 is formed in the fifth sub-via 901.

As an example, referring to FIG. 15A to FIG. 16, in the operation S662, a dry etching process may be used to etch the sub-stacked structure 1010 in the oz direction, to obtain a first initial sub-via (not shown) that exposes a portion of the substrate 10, is located between the second horizontal portion 42 and the read transistor 101, and is located between the first vertical portion 43 and the read word line 30. In the operation S662, a dry etching process and/or a wet etching process may be used to etch the sacrificial layer 11 in the ox direction and in the oy direction through the first initial sub-via, to obtain the fifth sub-via 901 that exposes a portion of the first semiconductor layer 104. In the operation S664, a deposition process may be used to form the read bit line 90 in the fifth sub-via 901. The cross section of the read bit line 90 parallel to the oz direction and the ox direction includes multiple “T” shapes. The read bit line 90 includes multiple main body portions extending along the oz direction, and branches extending at a sidewall of each of the main body portions toward the respective read transistor. The material of the read bit line 90 may be selected from copper, tungsten, aluminum, copper alloys, and combinations thereof.

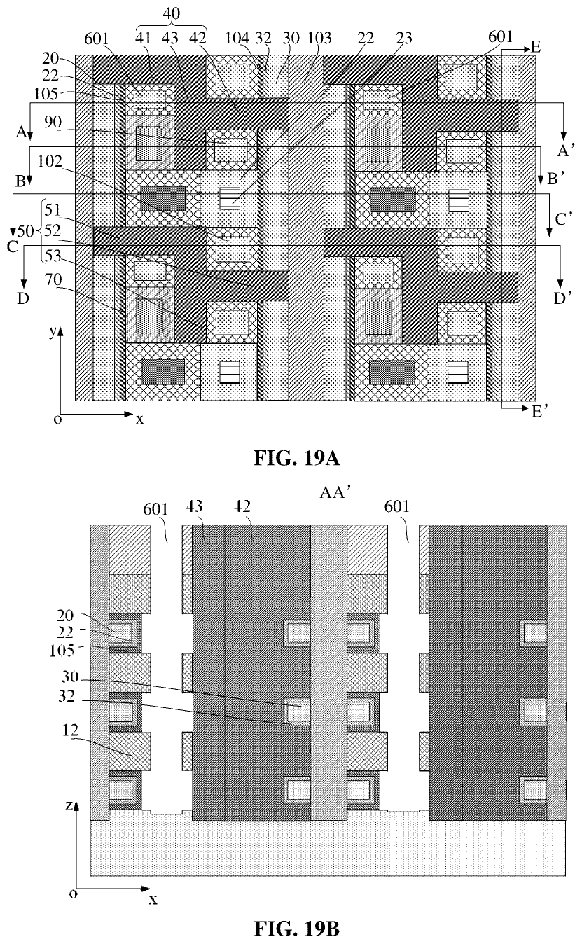

As an example, referring to FIG. 17A to FIG. 18, the second insulating structure 50 has a bent portion extending along the second direction (e.g. oy direction) and facing away from the insulating layer. After the insulating layer is formed in the third sub-via 8011 in the operation S658, the preparation method further includes the following operations S672 and S674.

In operation S672, a fourth sub-via 1021 is formed in a region surrounded by the bent portion of the second insulating structure 50 and the first semiconductor layer 104. The fourth sub-via 1021 exposes the drain contact region of the read transistor 101.

In operation S674, the reference line 102 is formed in the fourth sub-via 1021.

As an example, with continued reference to FIG. 17A to FIG. 18, in the operation S672, a dry etching process may be used to etch the sub-stacked structure 1010 in the oz direction, to obtain a second initial sub-via (not shown) that exposes a portion of the substrate 10, is located between the fourth horizontal portion 52 and the channel region of the read transistor 101, and is located between the second vertical portion 53 and the read word line 30. In the operation S674, a dry etching process and/or a wet etching process may be used to etch the sacrificial layer 11 in the ox direction and the oy direction through the second initial sub-via, to obtain the fourth sub-via 1021 that exposes the source contact region of the read transistor 101. In the operation S674, a deposition process may be used to form the reference line 102 in the fourth sub-via 1021. The reference line 102 is connected to the source contact region of the read transistor 101. The reference line 102 may be a grounding line. The cross section of the reference line 102 parallel to the oz direction and the ox direction includes multiple “T” shapes. The reference line 102 includes multiple main body portions extending along the oz direction, and branches extending at a sidewall of each of the main body portions toward the respective read transistor. The material of the reference line 102 may be selected from conductive metals, metal silicides, doped polysilicon, and combinations thereof.

As an example, referring to FIG. 19A to FIG. 21E, in the operation S60, the operation that the storage structures arranged in an array are formed on the substrate 10 based on the sub-stacked structures 1010 further includes the following operations S682 and S684.

In operation S682, a sixth sub-via 601 is formed in a region surrounded by the bent portion of the first insulating structure 40 and the second semiconductor layer 105. The sixth sub-via 601 exposes the drain contact region of the write transistor 70.

In operation S684, the write bit line 60 is formed in the sixth sub-via 601.

As an example, with continued reference to FIG. 19A to FIG. 21E, in the operation S682, a dry etching process may be used to etch the sub-stacked structure 1010 in the oz direction, to obtain a third initial sub-via (not shown) that exposes a portion of the substrate 10, is located between the first horizontal portion 41 and the channel region of the write transistor 70, and is located between the first vertical portion 43 and the write word line 20. In the operation S682, a dry etching process and/or a wet etching process may be used to etch the sacrificial layer 11 in the ox direction and the oy direction through the third initial sub-via, to obtain the sixth sub-via 601 that exposes the drain contact region of the write transistor 70. In the operation S684, a deposition process may be used to form the write bit line 60 in the sixth sub-via 601. The cross section of the write bit line 60 parallel to the oz direction and the ox direction includes multiple “T” shapes. The write bit line 60 includes multiple main body portions extending along the oz direction, and branches extending at a sidewall of each of the main body portions toward the respective write transistor. The material of the write bit line 60 may be selected from copper, tungsten, aluminum, copper alloys, and combinations thereof.

It should be understood that although the individual operations described in FIG. 1 and the previously described process flow are sequentially illustrated based on the indications of arrows or the stated order of the operations, these operations are not necessarily executed in sequence in the order indicated by the arrows. Unless explicitly stated herein, there is no strict sequential restriction on the execution of these operations, and these operations may be executed in other orders. Furthermore, at least a portion of the operations described in FIG. 1 and the previously described process flow may include multiple operations or multiple stages, which are not necessarily completed simultaneously but may be executed at different times. The execution sequence of these operations or stages is not necessarily sequential, but may be executed in turn or alternately with other operations or at least a portion of operations or stages in other operations.

In the foregoing embodiments, the preparation sequence of the write bit line, the write transistor, the storage node, the read bit line, the read transistor, and the reference line may be arbitrarily changed or combined. For example, the first sub-via and the second sub-via may be formed in the same process operation, and the fourth sub-via, the fifth sub-via and the sixth sub-via may also be formed in the same process operation. Therefore, any combination and/or exchange (performed by those skilled in the art without any creative efforts) of the preparation processes for any number of the following: the write bit line, the write transistor, the storage node, the read bit line, the read transistor, and the reference line, shall fall within the scope of protection of the embodiments of the disclosure.

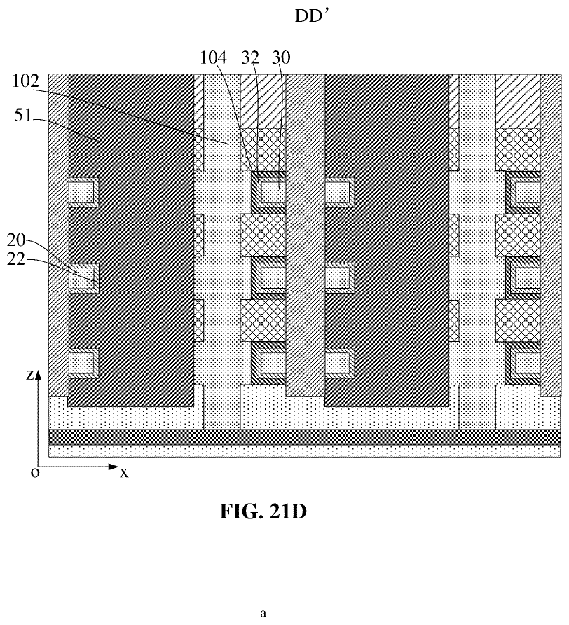

In some embodiments, with continued reference to FIG. 20 to FIG. 21E, a memory is provided. The memory includes a substrate 10, and multiple memory cells 100 stacked in a thickness direction perpendicular to a surface of the substrate 10. Each memory cell 100 includes: a write word line 20, a write transistor 70, a read transistor 101, and a read word line 30, which are sequentially distributed along a first direction; and a write bit line 60 and a read bit line 90, which are located between the write word line 20 and the read word line 30. The write word lines 20 and the read word lines 30 extend along a second direction parallel to the surface of the substrate 10. The write bit lines 60 and the read bit lines 90 extend to the substrate 10 along the direction perpendicular to the substrate. The write transistor 70 includes a source contact region, a drain contact region, and a channel region located between the source contact region and the drain contact region, which are sequentially distributed along the second direction. The read transistor 101 includes: a back-gate 1012; and a source contact region, a drain contact region and a channel region located between the source contact region and the drain contact region, which are sequentially distributed along the second direction. The back-gate 1012 is located between the write word line 20 and the channel region of the read transistor 101. The first direction intersects the second direction.

For the memory in the above embodiments, by disposing the write word lines 20 and the read word lines 30 to be spaced apart from each other in the first direction (e.g., the ox direction), and both extend along the second direction (e.g., the oy direction) parallel to the surface of the substrate 10; disposing the source contact region, the drain contact region, and the channel region (located between the source contact region and the drain contact region) of each write transistor 70, and the source contact region, the drain contact region, and the channel region (located between the source contact region and the drain contact region) of each read transistor 101, to be sequentially distributed along the oy direction, herein the write transistor 70 and the read transistor 101 are located between the write word line 20 and the read word line 30; and disposing each write bit line 60 and each read bit line 90 (which are located between a respective one of the write word lines 20 and a respective one of the read word lines 30) to extend along the direction (e.g., the oz direction) perpendicular to the substrate, this technical solution is quite different from the technical solution in the related art where “both the word lines and the bit lines extend along the direction parallel to the surface of the substrate 10”, the technical solution of the disclosure facilitates such memory cells to form a memory array with three-dimensional arrangement in the first direction, the second direction, and the thickness direction. Since two columns of memory cells adjacent in the first direction in the memory array can share a common read bit line/a common write bit line, it enables simultaneous access to write word lines 20 or read word lines 30 adjacent in the first direction. Consequently, a memory cell 100 is proposed in which the extension direction of the word lines is parallel to the surface of the substrate 10, and the extension direction of the bit lines is perpendicular to the surface of the substrate 10, which overcomes the technical bias that “the number of bytes accessed each time depends on the number of memory cells sharing a single word line”, effectively increasing the bandwidth of the data accessed each time and thereby enhancing the data transmission rate of the prepared product. Moreover, when the write transistor 70 is turned on, this memory cell 100 can provide an electrical signal to the storage node (SN) through the write bit line 60 and the write transistor 70 to achieve data writing. It also forms a storage data readout path containing the read word line 30, the read bit line 90, and the read transistor 101, to obtain the relative magnitude of the output electrical signal values through the storage data readout path, and to achieve the readout of the data through the storage data readout path. Therefore, in the embodiments of the disclosure, without relying on a capacitor structure, two transistors are utilized to achieve the writing and reading of stored data. This solution enables a reduction in the volume of the prepared product while ensuring no decrease in storage capacity, which enhances the storage density and integration level of the memory, effectively reduces the process complexity and preparation cost for preparing the memory, and improves the performance and reliability of the prepared memory.

In some embodiments, with continued reference to FIG. 20 to FIG. 21E, each back-gate 1012 includes a gate conductive layer 21 and a gate dielectric layer 22, and the dielectric layer 12 is disposed between any two adjacent memory cells stacked in the direction perpendicular to the substrate. The memory includes at least one first via that is located between the write word lines 20 and the read word lines 30 and penetrates through each memory cell. The embodiments of the disclosure take the example of one first via for illustration.

The gate dielectric layers 22 and the gate conductive layers 21 are sequentially disposed on the sidewalls of the first via. The gate conductive layers 21 corresponding to memory cells in different layers are insulated from each other through a dielectric layer 12. The region of the gate conductive layer 21 in the first via close to the write transistor 70 is connected to the corresponding source contact region, and the region of the gate conductive layer 21 close to the read transistor 101 is connected to the channel region of the read transistor 70 through the gate dielectric layer 22.

In some embodiments, with continued reference to FIG. 20 to FIG. 21E, an opening is disposed in a region of the gate dielectric layer 22 that is close to a corresponding write transistor 70, and the gate conductive layer 21 is electrically connected to the corresponding write transistor 70 at the opening in the region.

In some embodiments, with continued reference to FIG. 20 to FIG. 21E, the gate conductive layer 21 in at least one first via surrounds the sidewalls of the first via.

In some embodiments, with continued reference to FIG. 20 to FIG. 21E, in a region of the first via that corresponds to the gate conductive layer 21, an aperture of the region that is close to a middle region of the gate conductive layer 21 is larger than an aperture of the region that is close to each of two end regions of the gate conductive layer 21. The gate dielectric layer 22 forms an adaptive structure based on a shape of the first via.

In some embodiments, with continued reference to FIG. 20 to FIG. 21E, the gate conductive layer 21 is located between the write word line 20 and the channel region of the read transistor 101, and the gate conductive layers 21 adjacent in the direction (e.g., the oz direction) perpendicular to the substrate are insulated from each other. The gate conductive layer 21 includes a first surface close to the substrate 10 in the oz direction, a second surface facing away from the substrate 10 in the oz direction, a third surface close to the channel region of the read transistor 101 in the second direction (e.g., the oy direction), and a fourth surface facing away from the channel region of the read transistor 101 in the oy direction. The fourth surface is electrically connected to the write transistor 70. The gate dielectric layer 22 includes a first surface that covers the first surface of the gate conductive layer 21, a second surface that covers the second surface of the gate conductive layer 21, and a third surface that covers the third surface of the gate conductive layer 21. The third surface of the gate dielectric layer 22 is adjacent to the channel region of the read transistor 101. The gate dielectric layers 22 adjacent in the direction perpendicular to the substrate are insulated from each other. The insulating layer penetrates through the first surfaces of the gate conductive layers 21, the first surfaces of the gate dielectric layers 22, the second surfaces of the gate conductive layers 21, and the second surfaces of the gate dielectric layers 22 in the direction perpendicular to the substrate, and the insulating layer extends to the surface or inside of the substrate 10.

In some embodiments, with continued reference to FIG. 20 to FIG. 21E, the memory further includes first semiconductor layers 104 that extend along the second direction (e.g., the oy direction). Each first semiconductor layer 104 has two opposite main surfaces that are a first side and a second side of the first semiconductor layer 104, respectively. The first side of the first semiconductor layer 104 faces away from the read word line 30, and the second side of the first semiconductor layer 104 faces toward the read word line 30. The first semiconductor layer 104 includes a source contact region of the read transistor 101, a drain contact region of the read transistor 101, and a channel region located between the source contact region and the drain contact region, which are spaced apart from each other on the first side.

In some embodiments, with continued reference to FIG. 20 to FIG. 21E, the first semiconductor layer 104 surrounds a sidewall of the respective read word line 30 and is insulated from the read word line 30. The first side of the first semiconductor layer 104 includes an upper surface, a lower surface and a side surface. The source contact region, the channel region and the drain contact region of the read transistor 101 are at least partially located on the side surface and sequentially disposed along an extending direction of the read word line 30. Due to the fact that the gate length of the read transistor 101 is L and the gate width of the read transistor 101 is t+2 W, the gate width is effectively increased without increasing the volume of the read transistor 101, thereby significantly improving the performance of the read transistor 101.

In some embodiments, with continued reference to FIG. 20 to FIG. 21E, the memory further includes a second via and multiple conductive layers 82 located on the sidewalls of each of the second via. The second via is close to the channel regions of the write transistors and penetrates through each of memory cells in each layer. The conductive layers 82 corresponding to memory cells in different layers are insulated from each other through a dielectric layer 12. The second via exposes the source contact region of the write transistor 70 and the gate conductive layer 21 of the memory cell in each layer. Each conductive layer 82 is located on the sidewall of the second via and forms a ring structure, and the ring structure is simultaneously connected to the gate conductive layer 21 exposed by the second via and the source contact region of the write transistor. For example, the conductive layer 82 has a hole shape, and the hole-shaped conductive layer 82 is filled with an insulating layer. For another example, the insulating layer extends along the oz direction to the surface or inside of the substrate 10, and is located between the write word line 20 and the fourth surface of the gate conductive layer 21. The conductive layer 82 circumferentially surrounds the outer sidewall of the insulating layer, and the fourth surface of the gate conductive layer 21 is electrically connected to the write transistor 70 through the conductive layer 82. The equipotential point between the source contact region of the write transistor 70 and the back-gate 1012 is used to collectively form a storage node. The channel region of the read transistor 101, the first via, the second via and the source contact region of the write transistor 70 may be disposed to cover at least one straight line parallel to the first direction (e.g., the ox direction), to reduce the volume of the “2TOC” memory cell.

In some embodiments, with continued reference to FIG. 20 to FIG. 21E, the memory further includes the second semiconductor layers 105 that extend along the second direction (e.g., the oy direction). Each second semiconductor layer 105 has two opposite main surfaces that are a first side and a second side of the second semiconductor layer 105, respectively. The first side of the second semiconductor layer 105 faces away from the write word line 20, and the second side of the second semiconductor layer 105 faces towards the write word line 20. The second semiconductor layer 105 includes a source contact region of the write transistor 70, a drain contact region of the write transistor 70, and a channel region located between the source contact region and the drain contact region, which are spaced apart from each other on the first side. Due to the fact that the second semiconductor layer 105 for forming the source contact region, the channel region, and the drain contact region of the write transistor 70 is prepared in the process of preparing the write word line 20, the complexity of the preparation process of the write transistor 70 is effectively reduced.

In some embodiments, with continued reference to FIG. 20 to FIG. 21E, the second semiconductor layer 105 surrounds a sidewall of the respective write word line 20 and is insulated from the write word line 20. The first side of the second semiconductor layer 105 includes an upper surface, a lower surface and a side surface. The source contact region, the channel region and the drain contact region of the write transistor 70 are at least partially located on the side surface. Due to the fact that the gate length of the write transistor 70 is L and the gate width of the write transistor 70 is t+2W, the gate width is effectively increased without increasing the volume of the write transistor 70, thereby significantly enhancing the performance of the write transistor 70.

In some embodiments, with continued reference to FIG. 20 to FIG. 21E, the memory further includes a reference line 102. The reference line 102 extends in a direction perpendicular to the substrate, penetrates through the memory cells, and connects to read transistors of the memory cells. For example, the reference line 102 extends to the surface or inside of the substrate 10 in the oz direction. The read bit line 90, the read transistor 101, and the reference line 102 are sequentially arranged in the second direction (e.g., the oy direction). It can be determined without any doubt that the position of the reference line 102 and the position of the read bit line 90 may be interchanged. The reference line 102 may include multiple main body portions extending along the oz direction, and branches extending at a sidewall of each of the main body portions toward the respective read transistor 101. The reference line 102 may be a grounding line.

In some embodiments, with continued reference to FIG. 20 to FIG. 21E, the write bit line 60 and the read bit line 90 are located on the same side facing away from the back-gate 1012 in the second direction (e.g., the oy direction). For example, the write bit line 60 and the read bit line 90 are located on the same side of the read transistor 101 that faces away from the reference line 102 in the second direction (e.g., the oy direction). The write bit line 60 and the read bit line 90 are spaced apart and insulated from each other in the oy direction. The read bit line 90 and the write transistor 70 are spaced apart and insulated from in the first direction (e.g., the ox direction). This configuration reduces the volume of the memory cell while satisfying multiple different layout scenarios, thereby improving the integration of the memory cells in the memory and reducing the complexity and cost of preparation process.

In some embodiments, with continued reference to FIG. 20 to FIG. 21E, the write word line 20 connects different memory cells disposed in the second direction on the same layer. The write bit lines 60 and the read bit lines 90 connect the respective write transistors 70 and the respective read transistors 101 in the vertically stacked memory cells, respectively. For example, the memory further includes functional layers and dielectric layers on the substrate 10 that are alternately stacked in sequence in the direction (e.g., the oz direction) perpendicular to the substrate. The functional layers include memory cells 100 spaced apart from each other in the first direction (e.g., the ox direction), and/or memory cells 100 spaced apart from each other in the second direction (e.g., the oy direction). In a same functional layer, the memory cells 100 adjacent in the oy direction share a same write word line 20 extending along the oy direction and share a same read word line 30 extending along the oy direction. Among the different functional layers, the memory cells 100 adjacent in the direction (e.g., the oz direction) perpendicular to the substrate share a same write bit line 60 extending along the oz direction, and share a same read bit line 90 extending along the oz direction.

In some embodiments, with continued reference to FIG. 20 to FIG. 21E, the write bit line 60 includes multiple main body portions extending along the oz direction, and branches extending at a sidewall of each of the main body portions toward the write transistor 70. The cross section of the write bit line 60 parallel to the thickness direction (e.g., the oz direction) and the first direction (e.g., the ox direction) includes multiple “T” shapes.

In some embodiments, with continued reference to FIG. 20 to FIG. 21E, the read bit line 90 includes multiple main body portions extending along the oz direction, and branches extending at a sidewall of each of the main body portions toward the read transistor 101. The cross section of the read bit line 90 parallel to the thickness direction (e.g., the oz direction) and the first direction (e.g., the ox direction) includes multiple “T” shapes.

In some embodiments, with continued reference to FIG. 20 to FIG. 21E and FIG. 22 to FIG. 23, the memory further includes common write bit lines and/or common read bit lines. The write bit lines 60 of the memory cells 100 adjacent in the first direction are all connected to the same common write bit line. The read bit lines 90 of the memory cells 100 adjacent in the first direction (e.g., the ox direction) are all connected to the same common read bit line. The write bit lines 60 of the memory cells 100 adjacent in the second direction (e.g., the oy direction) are all connected to different common write bit lines. The read bit lines 90 of the memory cells 100 adjacent in the second direction (e.g., the oy direction) are all connected to different common read bit lines.

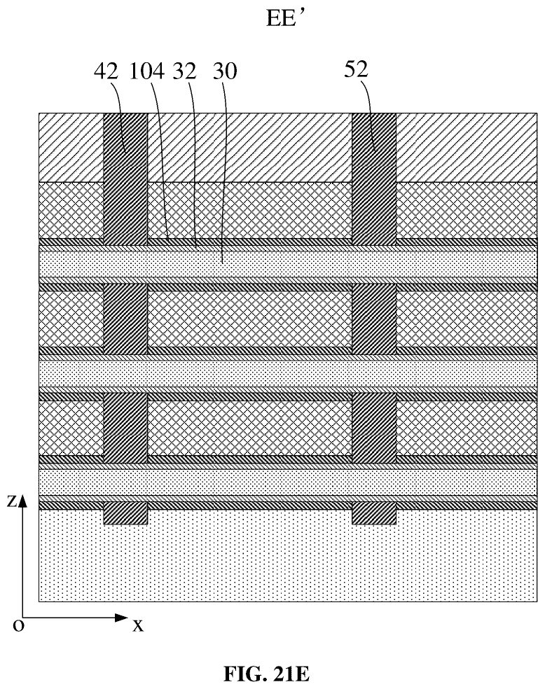

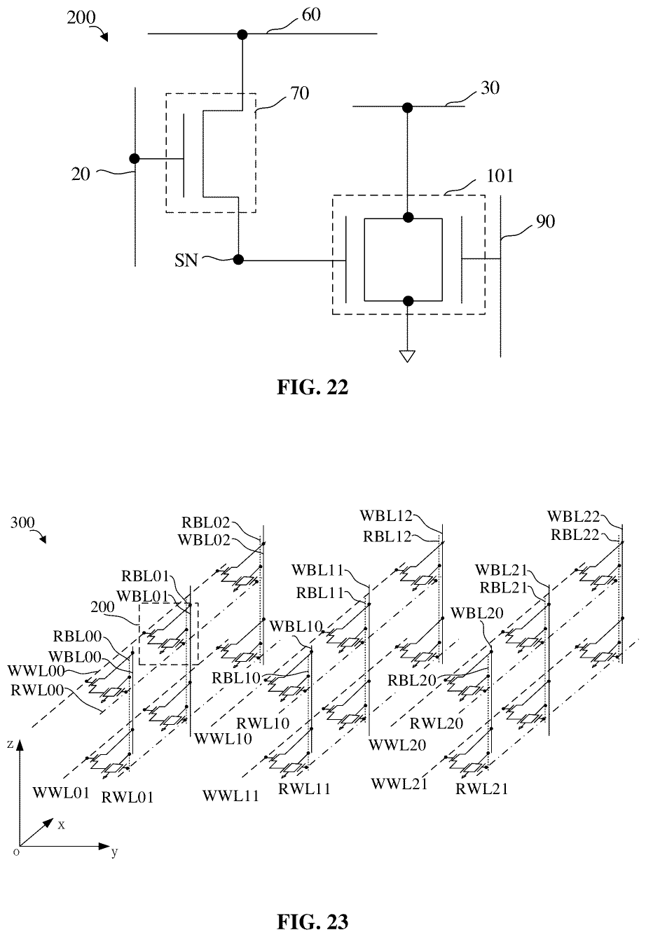

In some embodiments, with continued reference to FIG. 22 to FIG. 23, the common write bit lines and/or the common read bit lines extend along the first direction (e.g., the ox direction), and are located on the same side of the respective functional layer facing away from the substrate 10 in the direction perpendicular to the substrate (e.g., the oz direction).

In some embodiments, an electronic device is provided. The electronic device includes the memory as described in any one of the embodiments of the disclosure. The electronic device includes, for example, but is not limited to, an appropriate type of electronic product such as a consumer electronic product, a home electronic product, a vehicle-mounted electronic product, and a financial terminal product. The consumer electronic product is, for example, a mobile phone, a tablet computer, a notebook computer, a desktop monitor, an all-in-one computer, etc. The home electronic product is, for example, a smart door lock, a television, a refrigerator, a wearable device, etc. The vehicle-mounted electronic product is, for example, a vehicle-mounted navigator, a vehicle-mounted DVD, etc. The financial terminal product is, for example, an ATM machine, a self-service terminal, etc.

In some embodiments, referring to FIG. 22, a memory cell circuit 200 is provided. The memory cell circuit 200 includes a write word line 20, a read word line 30, a write transistor 70, and a read transistor 101. The write transistor 70 is configured such that: a first end of the write transistor 70 is electrically connected to the write bit line 60, a control end of the write transistor 70 is electrically connected to the write word line 20, and a second end of the write transistor 70 is electrically connected to the storage node (SN). The read transistor 101 is configured such that: a first end of the read transistor 101 is electrically connected to the read bit line 90, a first control end of the read transistor 101 is electrically connected to the storage node (SN), a second control end of the read transistor 101 is electrically connected to the read word line 30, and a second end of the read transistor 101 is electrically connected to the reference line 102. When the write word line 20 controls the write transistor 70 to be turned on, data is written to the storage node (SN) by providing a write signal to the write bit line 60. When the write transistor 70 is turned off, the conduction characteristic of the read transistor 101 is controlled by the read word line 30, and the data is read out based on the amplitude of the electric signal acquired through the read bit line 90.

For the memory cell circuit 200 in the above embodiments, when the write word line 20 controls the write transistor 70 to be turned on, data is written to the storage node (SN) by providing a write signal to the write bit line 60. When the write transistor 70 is turned off, the conduction characteristic of the read transistor 101 is controlled by the read word line 30, and the data is read out based on the amplitude of the electric signal acquired through the read bit line 90. For example, if the conduction characteristic of the read transistor 101 is relatively good and the amplitude of the electric signal (for example, a voltage signal or a current signal) acquired through the read bit line 90 is relatively large, it is determined that the data “1” is read out. On the other hand, when the conduction characteristic of the read transistor 101 is relatively poor and the amplitude of the electric signal acquired through the read bit line 90 is relatively small, it is determined that the data “0” is read out. Since the writing and reading of stored data are achieved by using only two transistors without relying on capacitor structures, the spatial volume occupied by the capacitor structures is avoided while ensuring no reduction in storage capacity per unit volume. As a result, it increases the storage density of the memory cells while enhancing performance and reliability of the memory cells.

In some embodiments, with continued reference to FIG. 22, the write transistor 70 and the read transistor 101 may be N-type transistors. The write transistor 70 and the read transistor 101 may also be P-type transistors. The write transistor 70 and the read transistor 101 may be of the same type or different types of transistors.

As an example, referring to FIG. 22 to FIG. 23, a memory array circuit 300 is provided. The memory array circuit 300 includes memory cell circuits 200 as described in any one of the embodiments of the disclosure, which are arranged in an array. The write word lines include write word lines WWLxy, the read word lines include RWLxy, the write bit lines include write bit lines WBLxy, and the read bit lines include read bit lines RBLxy, x∈[0, 2] The memory cell circuits 200 adjacent in the second direction (e.g., the oy direction) share the write word line and the read word line. The memory cell circuits 200 adjacent in the thickness direction (e.g., the oz direction) of the write word lines 20 share the write bit line and the read bit line. This configuration reduces the complexity of the wiring structure of the memory array circuit 300, lowers the wiring cost, and improves the operation performance and reliability of the memory array circuit 300.

As an example, the referring to FIG. 23, activation timings of the write word lines in memory cell circuits 200 adjacent in the first direction (e.g., the ox direction) are different, thereby preventing operational conflicts between the memory cell circuits 200 adjacent in the ox direction.

As an example, referring to FIG. 23, the write bit lines in memory cell circuits 200 adjacent in the first direction (e.g., the ox direction) are all connected to a common write bit line. The read bit lines of the memory cell circuits 200 adjacent in the ox direction are all connected to a common read bit line. The common write bit lines/common read bit lines connected to the memory cell circuits 200 adjacent in the second direction (e.g., oy direction) are different, which facilitates simplifying the wiring complexity of peripheral circuits while improving the efficiency of data transmission of semiconductor devices.

As an example, with continued reference to FIG. 22 to FIG. 23, a method for reading and writing a memory cell circuit 200 is provided. The memory cell circuit 200 includes a write word line 20, a read word line 30, a write transistor 70, and a read transistor 101. The write transistor 70 is configured such that: a first end of the write transistor 70 is electrically connected to the write bit line 60, a control end of the write transistor 70 is electrically connected to the write word line 20, and a second end of the write transistor 70 is electrically connected to the storage node (SN). The read transistor 101 is configured such that: a first end of the read transistor 101 is electrically connected to the read bit line 90, a first control end of the read transistor 101 is electrically connected to the storage node (SN), a second control end of the read transistor 101 is electrically connected to the read word line 30, and a second end of the read transistor 101 is electrically connected to the reference line 102. The method for reading and writing the memory cell circuit 200 includes the following operations.

When the write word line 20 controls the write transistor 70 to be turned on, data is written to the storage node (SN) by providing a write signal to the write bit line 60.

When the write transistor 70 is turned off, the conduction characteristic of the read transistor 101 is controlled through the read word line 30, the electric signal is acquired through the read bit line 90, and the data is acquired and read out based on the amplitude of the electric signal.

As an example, with continued reference to FIG. 22 to FIG. 23, when the write word line WWL00 is selected, if the write transistors of the memory cell circuits 200 electrically connected to the write word line WWL00 are controlled to be turned on through the write word line WWL00, data may be written to adjacent storage nodes through the write bit lines WBL0y (y∈[0, 2]). When the read word line RWL00 is selected, if the conduction characteristic of the read transistors of the memory cell circuits 200 electrically connected to the read word line RWL00 is controlled through the read word line RWL00, data may be read out from adjacent storage nodes through the read bit lines RBL0y (y∈[0, 2]). When the write transistor in the memory cell circuit 200 is turned off, the conduction characteristic of the read transistor is controlled through the read word line, and the data is read out based on the amplitude of the electric signal acquired through an adjacent read bit line. For example, when the amplitude of the electric signal (for example, a voltage signal or a current signal) acquired through the read bit line is relatively large, it is determined that the data “1” is read out; and when the amplitude of the electric signal acquired through the read bit line 90 is relatively small, it is determined that the data “0” is read out. Since the writing and reading of stored data are achieved by using only two transistors without relying on capacitor structures, the spatial volume occupied by the capacitor structures is avoided while ensuring no reduction in storage capacity per unit volume. As a result, it increases the storage density of the memory cells while enhancing performance and reliability of the memory cells.

As an example, referring to FIG. 22 to FIG. 23, a method for reading and writing a memory array circuit 300 is provided. The memory array circuit 300 includes memory cell circuits 200 as described in any one of the embodiments of the disclosure, which are arranged in an array along a first direction, a second direction, and a third direction. The memory cell circuits 200 adjacent in the first direction share a write word line 20 and a read word line 30. The memory cell circuits 200 adjacent in the third direction share a write bit line 60 and a read bit line 90. The third direction is perpendicular to the first direction and the second direction, and the first direction intersects the second direction. The method for reading and writing the memory array circuit 300 includes the following operations.

When the selected write word line 20 controls the write transistor 70 to be turned on, data is written to the storage node (SN) adjacent to the write transistor 70 by providing a write signal to the write bit line 60 adjacent to the write transistor 70.

When the write transistor 70 adjacent to the selected read bit line 90 is turned off, the conduction characteristic of the read transistor 101 adjacent to the selected read bit line 90 is controlled, the electric signal is acquired through the selected read bit line 90, and the data is acquired and read out based on the amplitude of the electric signal. The activation timings of the write word lines 20 of the memory cell circuits 200 adjacent in the second direction are different.

As an example, referring to FIG. 22 to FIG. 23, the write word lines include write word lines WWLxy, the read word lines include RWLxy, the write bit lines include write bit lines WBLxy, and the read bit lines include read bit lines RBLxy, x∈[0, 2]. The memory cell circuits 200 adjacent in the second direction (e.g., the oy direction) share the write word line and the read word line. The memory cell circuits 200 adjacent in the thickness direction (e.g., the oz direction) of the write word lines 20 share the write bit line and the read bit line. This configuration reduces the complexity of the wiring structure of the memory array circuit 300, lowers the wiring cost, and improves the operation performance and reliability of the memory array circuit 300.

As an example, with continued reference to FIG. 22 to FIG. 23, when the write word line WWL00 is selected, if the write transistors of the memory cell circuits 200 electrically connected to the write word line WWL00 are controlled to be turned on through the write word line WWL00, data may be written to adjacent storage nodes through the write bit lines WBL0y (y∈[0, 2]). When the read word line RWL00 is selected, if the conduction characteristic of the read transistors of the memory cell circuits 200 electrically connected to the read word line RWL00 is controlled through the read word line RWL00, data may be read out from adjacent storage nodes through the read bit lines RBL0y (y∈[0, 2]). When the write transistor in the memory cell circuit 200 is turned off, the conduction characteristic of the read transistor adjacent to the selected read bit line is controlled, and the data is read out based on the amplitude of the electric signal acquired through the adjacent read bit line. For example, when the amplitude of the electric signal (for example, a voltage signal or a current signal) acquired through the read bit line is relatively large, it is determined that the data “1” is read out; and when the amplitude of the electric signal acquired through the read bit line 90 is relatively small, it is determined that the data “0” is read out. Since the writing and reading of stored data are achieved by using only two transistors without relying on capacitor structures, the spatial volume occupied by the capacitor structures is avoided while ensuring no reduction in storage capacity per unit volume. As a result, it increases the storage density of the memory cells while enhancing performance and reliability of the memory cell.

In some embodiments, a computer device is provided. The computer device includes a memory for storing a computer program; and a processor for executing the computer program to implement the operations of any one of the methods for reading and writing the memory cell circuit or implement the operations of any one of the methods for reading and writing the memory array circuit described above.

In some embodiments, a computer-readable storage medium having stored thereon a computer program is provided. The computer program, when executed by a processor, implements implement the operations of any one of the methods for reading and writing the memory cell circuit or implement the operations of any one of the methods for reading and writing the memory array circuit described above.

In some embodiments, a computer program product containing a computer program is provided. The computer program, when executed by a processor, implements implement the operations of any one of the methods for reading and writing the memory cell circuit or implement the operations of any one of the methods for reading and writing the memory array circuit described above.

It will be understood by those ordinary skilled in the art that all or part of the processes in the methods of the above embodiments may be implemented by instructing related hardwares by a computer program; and the computer program may be stored in a non-volatile computer-readable storage medium, and when executed, the computer program may include the processes of the embodiments of the above methods. Any reference to memory, database or other medium used in the embodiments provided by the disclosure may include at least one of a non-volatile memory or a volatile memory. The non-volatile memory may include a read-only memory (ROM), a magnetic tape, a floppy disk, a flash memory, an optical memory, a high-density embedded non-volatile memory, a resistive random access memory (ReRAM), a magneto-resistive random access memory (MRAM), a ferroelectric random access memory (FRAM), a phase change memory (PCM), a graphene memory, etc. The volatile memory may include a random access memory (RAM) or an external cache memory. By way of illustration and not limitation, the RAM may take various forms, such as a static random access memory (SRAM) or a dynamic random access memory (DRAM), and the like. The database involved in the embodiments provided by the disclosure may include at least one of a relational database or a non-relational database. The non-relational database may include a blockchain-based distributed database or the like, but is not limited thereto. The processor involved in the embodiments provided by the disclosure may be a general-purpose processor, a central processing unit, a graphics processing unit, a digital signal processor, a programmable logic device, a data processing logic device based on quantum computing, and the like, but is not limited thereto. The technical features of the embodiments described above can be combined arbitrarily. For the sake of brevity in description, not all possible combinations of these technical features in the embodiments described above are described. However, any combination of these technical features without conflict should be considered within the scope of the description.

Note that the above embodiments are for illustrative purposes only and do not imply any limitation of the disclosure.

The embodiments in the description are described in a progressive manner, with each embodiment primarily highlighting the difference(s) from other embodiments. For identical or similar parts among the embodiments, reference may be made to each other accordingly.

The above embodiments merely represent several implementations of the disclosure, and the descriptions thereof are relatively specific and detailed. However, this should not be understood as a limitation on the scope of the disclosed patent. It should be noted that for those skilled in the art, modifications and improvements can be made without departing from the concept of the disclosure, and all of the modifications and improvements fall within the scope of protection of the disclosure.

1. A memory, comprising a substrate, write word lines, read word lines, write bit lines, read bit lines, and a plurality of memory cells stacked in a direction perpendicular to the substrate;
for each of the plurality of memory cells, the memory cell comprises a write transistor and a read transistor, which are located between a respective one of the write word lines and a respective one of the read word lines, and are sequentially distributed in a first direction parallel to the substrate;
for each of the write bit lines and each of the read bit lines, the write bit line and the read bit line are located between a respective one of the write word lines and a respective one of the read word lines, and are connected to a respective one of write transistors and a respective one of read transistors, respectively;
wherein the write word line and the read word line extend along a second direction parallel to the substrate, and the write bit line and the read bit line extend along the direction perpendicular to the substrate;
for each of the read transistors, the read transistor comprises a back-gate and a first semiconductor layer which extends along the second direction and surrounds a respective one of the read word lines; wherein the first semiconductor layer comprises: a source contact region, a drain contact region and a channel region located between the source contact region and the drain contact region, which are sequentially distributed along the second direction, and the back-gate is located between a respective one of the write word lines and the read transistor;
for each of the write transistors, the write transistor comprises a second semiconductor layer extending along the second direction and surrounding a respective one of the write word lines; wherein the second semiconductor layer comprises: a source contact region, a drain contact region and a channel region located between the source contact region and the drain contact region, which are sequentially distributed along the second direction; and
the first direction intersects the second direction.

2. The memory of claim 1, wherein the back-gate comprises at least a gate conductive layer and a gate dielectric layer;
the memory further comprises at least one first via that is located between the write word lines and the read word lines and penetrates through the plurality of the memory cells, wherein the gate dielectric layer and the gate conductive layer are sequentially disposed on sidewalls of each of the at least one first via; the gate conductive layers corresponding to memory cells in different layers are insulated from each other through a respective one of dielectric layers; a region of the gate conductive layer in the first via that is close to a respective one of the write transistors is connected to the source contact region of the write transistor, and a region of the gate conductive layer in the first via that is close to a respective one of the read transistors is connected to the read transistor through the gate dielectric layer.

3. The memory of claim 2, wherein an opening is disposed in a region of the gate dielectric layer that is close to a respective one of the write transistors, and the gate conductive layer is connected to the write transistor at the opening in the region.

4. The memory of claim 2, wherein the gate conductive layer in the at least one first via surrounds the sidewalls of the first via.

5. The memory of claim 2, wherein in a region of the first via that corresponds to the gate conductive layer, an aperture of the region that is close to a middle region of the gate conductive layer is larger than an aperture of the region that is close to each of two end regions of the gate conductive layer, and the gate dielectric layer forms an adaptive structure based on a shape of the first via.

6. The memory of claim 1, wherein the first semiconductor layer has two opposite main surfaces that are a first side and a second side of the first semiconductor layer, respectively; the first side faces away from the read word line, the second side faces toward the read word line; and the first semiconductor layer comprises: the source contact region of the read transistor, the drain contact region of the read transistor, and the channel region located between the source contact region and the drain contact region, which are spaced apart from each other on the first side.

7. The memory of claim 6, wherein the first semiconductor layer surrounds sidewalls of the read word line and is insulated from the read word line; the first side of the first semiconductor layer comprises an upper surface, a lower surface and a side surface; and the source contact region, the channel region and the drain contact region of the read transistor are at least partially located on the side surface and sequentially disposed in an extending direction of the read word line.

8. The memory of claim 2, further comprising:
a second via and a plurality of conductive layers located on a sidewall of the second via;
wherein the second via is close to the channel regions of the write transistors and penetrates through each of memory cells in each layer; and the conductive layers corresponding to the memory cells in different layers are insulated from each other;
the second via exposes the source contact regions of the write transistors and the gate conductive layers of the memory cells in each layer; and
each of the plurality of conductive layers is located on the sidewall of the second via and forms a ring structure, the ring structure simultaneously connecting to the gate conductive layer exposed by the second via and the source contact region of the write transistor.

9. The memory of claim 8, wherein the channel region of the read transistor, the first via, the second via and the source contact region of the write transistor covers at least one straight line parallel to the first direction.

10. The memory of claim 1, wherein the second semiconductor layer has two opposite main surfaces that are a first side and a second side of the second semiconductor layer, respectively; the first side faces away from the write word line, and the second side faces toward the write word line; the second semiconductor layer comprising the source contact region of the write transistor, the drain contact region of the write transistor, and the channel region located between the source contact region and the drain contact region, which are spaced apart from each other on the first side.

11. The memory of claim 10, wherein the second semiconductor layer surrounds sidewalls of the write word line and is insulated from the write word line; the first side of the second semiconductor layer comprises an upper surface, a lower surface and a side surface; and the source contact region, the channel region and the drain contact region of the write transistor are at least partially located on the side surface and sequentially disposed in an extending direction of the write word line.

12. The memory of claim 1, further comprising:
a reference line, which extends in the direction perpendicular to the substrate and penetrates through the plurality of the memory cells and connects to the read transistors of the plurality of the memory cells;
the read bit line, the back-gate and the reference line are sequentially arranged in the second direction.

13. The memory of claim 11, wherein the write bit line and the read bit line are on a same side facing away from a respective one of the back-gates in the second direction.

14. An electronic device, comprising:
the memory of claim

15. A preparation method for a memory, comprising:
providing a substrate;
forming a stacked structure on the substrate, the stacked structure comprises sacrificial layers and dielectric layers that are alternately stacked in sequence in a direction perpendicular to the substrate; and
forming, on the substrate based on the stacked structure, write word lines, read word lines, write bit lines, read bit lines, and a plurality of memory cells stacked in the direction perpendicular to the substrate; wherein for each of the plurality of memory cells, the memory cell comprises a write transistor and a read transistor, which are located between a respective one of the write word lines and a respective one of the read word lines and are sequentially distributed along a first direction parallel to the substrate; for each of the write word lines and each of the read word lines, the write word line and the read word line extend along a second direction parallel to the substrate; for each of the write bit lines and each of the read bit lines, the write bit line and the read bit line extend along the direction perpendicular to the substrate, are located between a respective one of the write word lines and a respective one of the read word lines, and are connected to a respective one of write transistors and a respective one of read transistors, respectively; for each of the read transistors, the read transistor comprises a back-gate and a first semiconductor layer which extends along the second direction and surrounds a respective one of the read word lines; the first semiconductor layer comprises: a source contact region, a drain contact region and a channel region located between the source contact region and the drain contact region, which are sequentially distributed along the second direction; the back-gate is located between a respective one of the write word lines and the channel region of the read transistor; for each of the write transistors, the write transistor comprises a second semiconductor layer extending along the second direction and surrounding a respective one of the write word lines; the second semiconductor layer comprises: a source contact region, a drain contact region and a channel region located between the source contact region and the drain contact region, which are sequentially distributed along the second direction; and the first direction intersects the second direction.

16. The preparation method of claim 15, wherein forming, on the substrate based on the stacked structure, the write word lines, the read word lines, the write bit lines, the read bit lines, and the plurality of memory cells stacked in the direction perpendicular to the substrate comprises:
forming, on the stacked structure, two isolation trenches extending along the second direction and penetrating through the stacked structure, wherein the two isolation trenches respectively expose sacrificial layers and dielectric layers, which are respectively located on two opposite sidewalls of the stacked structure; and etching back each of the exposed sacrificial layers to form a first accommodating groove and a second accommodating groove, which are located on two opposite sidewalls of the exposed sacrificial layer, respectively;
sequentially forming an initial semiconductor layer, a gate dielectric layer and a word line material layer on inner walls of the first accommodating grooves and on inner walls of the second accommodating grooves, wherein the word line material layer located in the first accommodating grooves is used to form the write word lines, and the word line material layer located in the second accommodating grooves is used to form the read word lines; and
removing a portion of the initial semiconductor layer, a portion of the gate dielectric layer and a portion of the word line material layer that are located within the isolation trench, to disconnect semiconductor layers and word lines of two memory cells adjacent in the first direction to form: initial first semiconductor layers that are disconnected from each other across different layers, initial second semiconductor layers that are disconnected from each other across different layers, the read word lines that are disconnected from each other across different layers, and the write word lines that are disconnected from each other across different layers.

17. The preparation method of claim 16, wherein after forming the write word lines and the read word lines, the preparation method further comprises:
forming, in the stack structure, first trenches and second trenches, which extend along the first direction and are spaced apart from each other in the second direction, to define a shape and a position of a single memory cell; wherein each of the first trenches and each of the second trenches disconnect a respective one of the initial first semiconductor layers and a respective one of the initial second semiconductor layers, and expose a portion of the substrate, a portion of an outer surface of the gate dielectric layer on the word line material layer that is close to the sacrificial layer, to disconnect the second semiconductor layers between different memory cells connected through a same write word line and the first semiconductor layers between different memory cells connected through a same read word line; and
filling the first trench and the second trench with an insulating layer to form a first insulating structure and a second insulating structure.

18. The preparation method of claim 17, wherein the first insulating structure has a bent portion extending along the second direction; the second semiconductor layer has two opposite main surfaces that are a first side and a second side of the second semiconductor layer, respectively; the first side faces away from the write word line, and the second side faces toward the write word line; the second semiconductor layer comprises the source contact region of the write transistor, the drain contact region of the write transistor and the channel region located between the source contact region and the drain contact region, which are spaced apart from each other on the first side;
after forming the first insulating structure and the second insulating structure, the preparation method further comprises:
etching the stacked structure in the direction perpendicular to the substrate, to obtain a first sub-via that exposes a portion of the substrate and is located in a region surrounded by the first insulating structure and the write word line;
etching the sacrificial layer in the first direction and the second direction through the first sub-via, to obtain a first accommodating recess for defining a channel length of the write transistor, wherein a portion of a side surface of the second semiconductor layer that is exposed by the first accommodating recess is used to form the channel region of the write transistor; and
forming an isolation layer in the first accommodating recess, to form write transistors that are insulated from each other in the direction perpendicular to the substrate.

19. The preparation method of claim 18, wherein the first semiconductor layer has two opposite main surfaces that are a first side and a second side of the first semiconductor layer, respectively; the first side faces away from the read word line, and the second side facing toward the read word line; and the first semiconductor layer comprises: the source contact region of the read transistor, the drain contact region of the read transistor, and the channel region located between the source contact region and the drain contact region, which are spaced apart from each other on the first side;
after forming the isolation layer in the first accommodating recess, the preparation method further comprises:
etching the stacked structure in the direction perpendicular to the substrate, to obtain a second sub-via that exposes a portion of the substrate and is located between the bent portion of the first insulating structure and the first semiconductor layer;
etching the sacrificial layer in the first direction and the second direction through the second sub-via, to obtain a second accommodating recess for defining a channel length of the read transistor, wherein a portion of a side surface of the first semiconductor layer that is exposed by the second accommodating recess is used to form the channel region of the read transistor;
sequentially forming a gate dielectric layer and a gate conductive layer in the second accommodating recess, to obtain the second sub-via, wherein the gate dielectric layer covers an inner wall of the second sub-via; and
forming an insulating layer in the second sub-via, to form the back-gates that are insulated from each other in the direction perpendicular to the substrate, wherein the insulating layer, the gate conductive layer and the gate dielectric layer are used to jointly form the back-gate.

20. The manufacturing method of claim 19, wherein after forming the insulating layer in the second sub-via, the preparation method further comprises:
etching the stacked structure in the direction perpendicular to the substrate, to obtain a third sub-via that exposes a portion of the substrate and is located in a region surrounded by the second insulating structure, the back-gate, the first insulating structure and the second semiconductor layer;
etching the sacrificial layer in the first direction and the second direction through the third sub-via, to obtain a third accommodating recess that exposes the source contact region of the write transistor and the gate conductive layer of the back-gate;
forming a conductive layer in the third accommodating recesses to obtain the third sub-via;
forming an insulating layer in the third sub-via, and forming a fourth sub-via in a region surrounded by a bent portion of the second insulating structure and the first semiconductor layer; wherein the fourth sub-via exposes the source contact region of the read transistor;
forming a reference line in the fourth sub-via, and forming a fifth sub-via in a region surrounded by the bent portion of the first insulating structure and the first semiconductor layer, wherein the fifth sub-via exposes the drain contact region of the read transistor;
forming a respective one of the read bit lines in the fifth sub-via;
forming a sixth sub-via in a region surrounded by the bent portion of the first insulating structure and the second semiconductor layer, wherein the sixth sub-via exposes the drain contact region of the write transistor; and
forming a respective one of the write bit lines in the sixth sub-via.
